(19) United States
(12) Patent Application Publication
(10) Pub. No.: US 2009/0203215 A1
(43) Pub. Date: Aug. 13, 2009

(54) METAL POLISHING SLURRY AND CHEMICAL MECHANICAL POLISHING METHOD

(75) Inventors: Masaru YOSHIKAWA, Haibara-gun (JP); Tadashi INABA, Haibara-gun (JP); Hiroshi INADA, Haibara-gun (JP); Takamitsu TOMIGA, Haibara-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 12/368,038

(22) Filed: Feb. 9, 2009

(30) Foreign Application Priority Data
Feb. 13, 2008 (JP) 2008-031864
Mar. 24, 2008 (JP) 2008-075401

(51) Int. Cl. H01L 21/304; C09K 13/00

(52) U.S. Cl. 438/693; 252/79.1; 257/E21.23

(57) ABSTRACT

A metal polishing slurry which is capable of simultaneously realizing a high polishing speed and reduced dishing in the polishing of a subject to be polished is provided. The metal polishing slurry includes a compound represented by the following general formula (1):

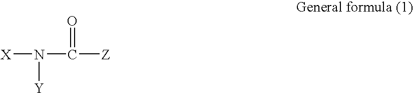

wherein X represents a heterocyclic group containing at least one nitrogen atom, Y represents hydrogen atom, an aliphatic hydrocarbon group, an aryl group, or a —C(═O)Z′ wherein Z′ is as defined for Z, and Z represents hydrogen atom, an optionally substituted aliphatic hydrocarbon group, an optionally substituted aryl group, an optionally substituted heterocyclic group, —NZ¹Z², or —OZ³ wherein Z¹, Z², and Z³ independently represent hydrogen atom, an optionally substituted aliphatic hydrocarbon group, an optionally substituted aryl group, or an optionally substituted heterocyclic group, with the proviso that Y and Z may together form a ring; an oxidizing agent; and an organic acid.

### BACKGROUND OF THE INVENTION

This invention relates to a metal polishing slurry for use in chemical mechanical polishing planarization in the manufacture of semiconductor devices. This invention also relates to a polishing method using such metal polishing slurry.

In the development of semiconductor devices such as semiconductor integrated circuits (hereinafter referred to as “LSI devices”), the trend toward smaller sizes and higher processing speeds has created a need in recent years for higher density and higher integration by the adoption of miniaturization and multilayer constructions of interconnection. Various techniques are being used to this end, including chemical mechanical polishing (hereinafter also referred to as “CMP”).

CMP is an essential technique for carrying out, for example, the surface planarization of a film to be processed (e.g., an interlayer dielectric film), plug formation, and buried metal interconnect formation, and this technology is used to carry out substrate planarization and to remove surplus metal thin film during the formation of interconnections. (See U.S. Pat. No. 4,944,836 B and JP 2-278822 A.)

CMP generally involves attaching a polishing pad onto a circular platen, impregnating the surface of the polishing pad with a polishing slurry, pressing the right side of a substrate (wafer) against the pad, and rotating both the platen and the substrate while applying a predetermined pressure (polishing pressure) from the back side of the substrate so as to planarize the right side of the substrate by the mechanical friction that arises.

The metal polishing slurry used in CMP typically includes fine abrasive particles (such as alumina and silica) and an oxidizer (such as hydrogen peroxide). It is believed that polishing takes place with oxidization of the metal surface by the oxidizer and removal of the resulting oxide film by the abrasive. The detailed procedure is described, for example, in Journal of Electrochemical Society, 1991, vol. 138, No. 11, pages 3460 to 3464.

However, the CMP conducted by using such metal polishing slurry containing the solid abrasive is associated with the risk of scratches formed by the polishing (scratches), excessive polishing of the entire polishing surface (thinning), deformation of the polished metal surface in the shape of a dish (dishing), and excessive polishing of the insulator between the metal wiring and dish-shape deformation of the wired metal surface (erosion).

JP 8-64594 A and JP 8-83780 A, for example, refer to incorporation of 1,2,3-benzotriazole (hereinafter also referred to as BTA) or 2-aminothiazole in the polishing slurry as a means for effectively suppressing such drawbacks, and in particular, the dishing. More specifically, BTA is brought in contact with the Cu film to thereby form a protective film containing the BTA on the Cu film or natural oxidized film so that the protective film formed may function as a barrier for preventing oxidation or etching.

### SUMMARY OF THE INVENTION

However, in the investigation by the inventors of the present invention, BTA reacted with the metal, and in particular, with the copper to form an extremely strong film which resulted in the unduly low polishing speed. In addition, dishing was only suppressed to an insufficient degree. In other words, these methods were unsatisfactory in simultaneously realizing prevention of the dishing and high polishing speed. With the increase in the density and integrity of the recent LSI, there is also a demand for a polishing slurry which enables polishing at a high performance and high productivity.

In view of the situation as described above, an object of the present invention is to provide a metal polishing slurry which is capable of simultaneously realizing a high polishing speed and reduced dishing in the polishing of a subject to be polished (wafer). Another object of the present invention is to provide a chemical mechanical polishing method using such metal polishing slurry.

The inventors of the present invention made an intensive study for obviating the problems as described above, and found that such problems can be obviated by using a metal polishing slurry containing a compound having a particular structure. The present invention has been completed on the basis of such finding.

Accordingly, the present invention provides the following [1] to [13].
[1] A metal polishing slurry used for chemical mechanical polishing in producing a semiconductor device, wherein the metal polishing slurry comprises

a compound represented by the following general formula (1):

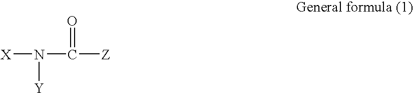

wherein X represents a heterocyclic group containing at least one nitrogen atom, Y represents hydrogen atom, an aliphatic hydrocarbon group, an aryl group, or a —C(═O)Z′ wherein Z′ is as defined for Z, and Z represents hydrogen atom, an optionally substituted aliphatic hydrocarbon group, an optionally substituted aryl group, an optionally substituted heterocyclic group, —NZ¹Z², or —OZ³ wherein Z¹, Z², and Z³ independently represent hydrogen atom, an optionally substituted aliphatic hydrocarbon group, an optionally substituted aryl group, or an optionally substituted heterocyclic group, with the proviso that Y and Z may together form a ring,

an oxidizing agent, and

an organic acid.
[2] The metal polishing slurry according to [1] wherein Z in the general formula (1) is —NZ¹Z².
[3] The metal polishing slurry according to [1] or [2] wherein X in the general formula (1) is tetrazole or 1,2,3-triazole.
[4] The metal polishing slurry according to [1] wherein Y in the general formula (1) is hydrogen atom.
[5] The metal polishing slurry according to [1] wherein the substituent for the optionally substituted aliphatic hydrocarbon group, aryl group, and heterocyclic group of Z and the optionally substituted aliphatic hydrocarbon group, aryl group, and heterocyclic group of Z¹, Z², and Z³ in the general formula (1) is at least one member selected from hydroxy group, amino group, ether group, amide group, sulfonamide group, sulfonimide group, carboxy group, sulfo group, quaternary ammonium group, imidazolium group, and phospho group.
[6] The metal polishing slurry according to [1] wherein the aliphatic hydrocarbon group, the aryl group, and the heterocyclic group of Z and the aliphatic hydrocarbon group, the aryl group, and the heterocyclic group of Z¹, Z², and Z³ in the general formula (1) are substituted with hydroxy group.
[7] The metal polishing slurry according to [1] further comprising an abrasive.
[8] The metal polishing slurry according to [7] wherein the abrasive is colloidal silica.
[9] The metal polishing slurry according to [8] wherein the colloidal silica has a primary particle size of 20 to 40 nm and an average degree of association of up to 2.
[10] The metal polishing slurry according to [8] or [9] wherein the colloidal silica is the colloidal silica in which at least a part of the silicon atoms on the surface are modified with aluminum atom.
[11] The metal polishing slurry according to [1] further comprising a surfactant represented by the following general formula (2):

R-Ar-O-Ar-SO₃³¹ M⁺ General formula (2)

wherein R represents a linear or branched alkyl group containing 8 to 20 carbon atoms, Ar represents aryl group, and M⁺ represents hydrogen ion, an alkali metal ion, or ammonium ion.
[12] The metal polishing slurry according to [1] wherein the organic acid is amino acid.
[13] A chemical mechanical polishing method for polishing an object having a surface to be polished, wherein the metal polishing slurry of [1] is supplied to a polishing pad on a polishing platen while rotating the polishing platen to move the polishing pad in relation to the surface to be polished of the object which is in contact with the polishing pad to thereby polish the surface to be polished of the object.

The present invention provides a metal polishing slurry which is capable of simultaneously realizing the high polishing speed and the reduced dishing. The present invention also provides a chemical mechanical polishing method using such metal polishing slurry. The present invention also realizes control of the defects such as scratches to a low level.

### DETAILED DESCRIPTION OF THE INVENTION

Next, the present invention is described in further detail by referring to the preferred embodiments.

The metal polishing slurry of the present invention is a polishing slurry used for the chemical mechanical polishing in the production of a semiconductor device, and contains a compound represented by the following general formula (1), an oxidizing agent, and an organic acid.

Next, each component is described in detail.

### [The Compound Represented by the Following General Formula (1)]

The metal polishing slurry of the present invention contains at least one compound represented by the general formula (1):

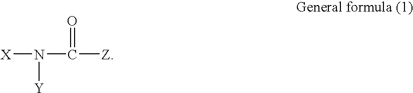

In the general formula (1), X represents a heterocyclic group containing at least one nitrogen atom, and Y represents hydrogen atom, an aliphatic hydrocarbon group, an aryl group, or a —C(—O)Z′ wherein Z′ is as defined for Z. Z represents hydrogen atom, an optionally substituted aliphatic hydrocarbon group, an optionally substituted aryl group, an optionally substituted heterocyclic group, —NZ¹Z², or —OZ³ wherein Z¹, Z², and Z³ independently represent hydrogen atom, an optionally substituted aliphatic hydrocarbon group, an optionally substituted aryl group, or an optionally substituted heterocyclic group. Y and Z may together form a ring.

In general formula (1), X represents a heterocyclic group containing at least one nitrogen atom. The heterocyclic group is not limited for the number of atoms constituting the ring, and it may be either a monocyclic ring or a polycyclic ring containing fused rings. In the case of a monocyclic ring, it may preferably comprise 3 to 8 atoms, more preferably 4 to 7 atoms, and most preferably 5 to 6 atoms. In the case of the group containing fused rings, it may preferably comprise 2 to 4 rings, and more preferably 2 rings. The heterocyclic group may be either an aromatic group or a non-aromatic group.

The heterocyclic group represented by X may contain sulfur atom, oxygen atom, selenium atom, tellurium atom, phosphorus atom, silicon atom, and boron atom in addition to the carbon atom, hydrogen atom, and nitrogen atom. The number of nitrogen atoms in X is typically at least 1, preferably at least 2, and more preferably at least 3.

Examples of the heterocyclic group represented by X in the general formula (1) include pyrrole ring, imidazole ring, pyrazole ring, thiazole ring, isothiazole ring, oxazole ring, isoxazole ring, pyridine ring, pyrazine ring, pyrimidine ring, pyridazine ring, pyrrolidine ring, pyrazolidine ring, imidazolidine ring, isoxazolidine ring, isothiazolidine ring, piperidine ring, piperazine ring, morpholine ring, thiomorpholine ring, indoline ring, isoindoline ring, pyrindine ring, indolizine ring, indole ring, indazole ring, purine ring, quinolizine ring, isoquinoline ring, quinoline ring, naphthyridine ring, phthalazine ring, quinoxaline ring, quinazoline ring, cinnoline ring, pteridine ring, acridine ring, perimidine ring, phenanthroline ring, carbazole ring, carboline ring, phenazine ring, anthyridine ring, thiadiazole ring, oxadiazole ring, triazine ring, 1,2,3-triazole ring, 1,2,4-triazole ring, tetrazole ring, benzimidazole ring, benzoxazole ring, benzothiazole ring, benzothiadiazole ring, benzofuroxan ring, naphthoimidazole ring, benzotriazole ring, and tetraazaindene ring. The preferred are tetrazole ring, 1,2,4-triazole ring, 1,2,3-triazole ring, and benzotriazole ring, and the most preferred are tetrazole ring and 1,2,3-triazole.

The heterocyclic group represented by X may be substituted by a substituent. Examples of such substituent which may be introduced in the heterocyclic group include halogen atom (fluorine atom, chlorine atom, bromine atom, or iodine atom), alkyl group (which may be a linear, branched, or cyclic alkyl group including polycyclic alkyl group such as bicycloalkyl group, and which may contain active methine group), alkenyl group, alkynyl group, aryl group, heterocyclic group (which is not limited by the position of the substitution), acyl group, alkoxycarbonyl group, aryloxycarbonyl group, heterocyclic oxycarbonyl group, carbamoyl group (which is optionally substituted as in the case of N-hydroxycarbamoyl group, N-acyl carbamoyl group, N-sulfonyl carbamoyl group, N-carbamoyl carbamoyl group, thiocarbamoyl group, or N-sulfamoyl carbamoyl group), carbazoyl group, carboxy group or its salt, oxalyl group, oxamoyl group, cyano group, carbonimidoyl group, formyl group, hydroxy group, alkoxy group (including the group containing ethylenoxy group or propylenoxy group as its repeating unit), aryloxy group, heterocyclic oxy group, acyloxy group, (alkoxy or aryloxy) carbonyloxy group, carbamoyloxy group, sulfonyloxy group, amino group, (alkyl, aryl, or heterocyclic) amino group, acylamino group, sulfonamide group, ureido group, thioureido group, N-hydroxy ureido group, imide group, (alkoxy or aryloxy) carbonylamino group, sulfamoylamino group, semicarbazide group, thiosemicarbazide group, hydrazino group, ammonio group, oxamoylamino group, N-(alkyl or aryl) sulfonyl ureido group, N-acyl ureido group, N-acyl sulfamoylamino group, hydroxyamino group, nitro group, heterocyclic group containing quaternarized nitrogen atom (for example, pyridinio group, imidazolio group, quinolinio group, or isoquinolinio group), isocyano group, imino group, mercapto group, (alkyl, aryl, or heterocyclic) thio group, (alkyl, aryl, or heterocyclic) dithio group, (alkyl or aryl) sulfonyl group, (alkyl or aryl) sulfinyl group, sulfo group or its salt, sulfamoyl group (which is optionally substituted as in the case of N-acyl sulfamoyl group or N-sulfonyl sulfamoyl group) or its salt, phosphino group, phosphinyl group, phosphinyloxy group, phosphinylamino group, and silyl group.

Among these, the preferred are halogen atom, alkyl group, aryl group, heterocyclic group, acyl group, alkoxycarbonyl group, aryloxycarbonyl group, heterocyclic oxycarbonyl group, carbamoyl group, hydroxy group, alkoxy group, aryloxy group, heterocyclic oxy group, acyloxy group, amino group, (alkyl, aryl, or heterocyclic) amino group, acylamino group, sulfonamide group, ureido group, thioureido group, and N-hydroxyureido group, and the more preferred are alkyl group, aryl group, heterocyclic group, carbamoyl group, hydroxy group, alkoxy group, aryloxy group, amino group, (alkyl, aryl, or heterocyclic) amino group, and ureido group. When X is substituted with two or more substituents, the substituents may be either the same or different.

Y in the general formula (1) represents hydrogen atom, an aliphatic hydrocarbon group, an aryl group, or —C(═O)Z′.

Exemplary aliphatic hydrocarbon groups represented by Y in the general formula (1) include alkyl group, alkenyl group (which mean in the present invention an unsaturated aliphatic group having a double bond including cycloalkenyl group and bicycloalkenyl group), and alkynyl group.

The alkyl group is not particularly limited, and may be an optionally substituted linear, branched, or cyclic alkyl group. In the case of a linear or a branched alkyl group, it may preferably contain 1 to 30, more preferably 1 to 20, and most preferably 1 to 10 carbon atoms. Exemplary alkyl groups include methyl group, ethyl group, n-propyl group, isopropyl group, tert-butyl group, n-octyl group, eicosyl group, 2-chloro ethyl group, 2-cyanoethyl group, trifluoromethyl group, and 2-ethylhexyl group, and the preferred are methyl group and ethyl group.

Exemplary cyclic alkyl groups include cycloalkyl group, bicycloalkyl group, and tricycloalkyl group. The cycloalkyl group preferably contains 3 to 30, more preferably 4 to 20, and most preferably 5 to 10 carbon atoms, and examples include cyclohexyl group, cyclopentyl group, and 4-n-dodecylcyclohexyl group, among which the cyclohexyl group being the most preferred. The bicycloalkyl group preferably contains 3 to 30, more preferably 4 to 20, and most preferably 5 to 12 carbon atoms, and examples include bicyclo[1.2.2]heptan-2-yl group and bicyclo[2.2.2]octan-3-yl group. The alkyl group may be substituted with a substituent, and examples of such substituent are those described above for the substituent of the heterocyclic group represented by X. When Y is substituted with two or more substituents, the substituents may be either the same or different.

The alkenyl group is not particularly limited, and may be an optionally substituted linear, branched, or cyclic alkenyl group. In the case of a linear or a branched alkenyl group, it may preferably contain 2 to 30, more preferably 2 to 20, and most preferably 2 to 10 carbon atoms. Exemplary alkenyl groups include vinyl group, allyl group, prenyl group, geranyl group, and oleyl group, and the preferred are vinyl group and allyl group. The cycloalkenyl group preferably contains 3 to 30, more preferably 3 to 20, and most preferably 5 to 10 carbon atoms, and examples include 2-cyclopentene-1-yl group and 2-cyclohexene-1-yl group. The bicycloalkyl group preferably contains 3 to 30, more preferably 3 to 20, and most preferably 5 to 12 carbon atoms, and examples include bicyclo[2.2.1]hept-2-en-1-yl group and bicyclo[2.2.2]oct-2-en-4-yl group. The alkenyl group may be substituted with a substituent, and examples of such substituent are those described above for the substituent of the heterocyclic group represented by X. Among these exemplary substituents, the preferred are an alkyl group (such as methyl group or ethyl group), an aryl group (such as phenyl group), and hydroxy group. When Y is substituted with two or more substituents, the substituents may be either the same or different.

The alkynyl group is not particularly limited, and may be an optionally substituted linear, branched, or cyclic alkynyl group. In the case of a linear or a branched alkynyl group, it may preferably contain 2 to 30, more preferably 3 to 20, and most preferably 3 to 10 carbon atoms. The alkynyl group may be substituted with a substituent, and examples of such substituent are those described above for the substituent of the heterocyclic group represented by X. Among these exemplary substituents, the preferred are an alkyl group (such as methyl group or ethyl group), an aryl group (such as phenyl group), and hydroxy group. When Y is substituted with two or more substituents, the substituents may be either the same or different. Exemplary alkynyl groups include ethynyl group and propargyl group.

The aryl group represented by Y is not particularly limited as long as it is aromatic, and the aryl group preferably contains 6 to 30, more preferably 6 to 20, and most preferably 6 to 12 carbon atoms. The aryl group may be substituted with a substituent, and examples of such substituent are those described above for the substituent of the heterocyclic group represented by X. Among these exemplary substituents, the preferred are an alkyl group (such as methyl group or ethyl group), an aryl group (such as phenyl group), and hydroxy group. When Y is substituted with two or more substituents, the substituents may be either the same or different. Exemplary aryl groups include phenyl group, p-tolyl group, naphthyl group, m-chlorophenyl group, and o-hexadecanoylaminophenyl group, and the preferred are phenyl group, p-tolyl group, and naphthyl group.

In the —C(═O)Z′ represented by Y, Z′ is as defined below for Z.

Y in the general formula (1) is preferably hydrogen atom or —C(═O)Z′, and more preferably hydrogen atom.

Z represents hydrogen atom, an optionally substituted aliphatic hydrocarbon group, an optionally substituted aryl group, an optionally substituted heterocyclic group, —NZ¹Z², or —OZ³ wherein Z¹, Z², and Z³ independently represent hydrogen atom, an optionally substituted aliphatic hydrocarbon group, an optionally substituted aryl group, or an optionally substituted heterocyclic group. Z¹ and Z² may be the same or different. Z is preferably an optionally substituted aryl group, an optionally substituted heterocyclic group, a —NZ¹Z², or a —OZ³, and more preferably —NZ¹Z². At least one of Z¹ and Z² in the —NZ¹Z² is preferably hydrogen atom, and more preferably, Z¹ and Z² are hydrogen atom or an optionally substituted aliphatic hydrocarbon group.

The aliphatic hydrocarbon group, aryl group, and heterocyclic group represented by Z and the aliphatic hydrocarbon group, aryl group, and heterocyclic group represented by Z¹, Z², and Z³ in the general formula (1) are preferably substituted by a substituent selected from the group consisting of hydroxy group, amino group, ether group, amide group, sulfonamide group, sulfonimide group, carboxy group, sulfo group, quaternary ammonium group, imidazolium group, and phospho group; and more preferably, the substituent is hydroxy group in view of the reduced scratches in the polishing. When substituted by two or more substituents, they may be either the same or different.

The aliphatic hydrocarbon group represented by Z may be the same as those defined for the aliphatic hydrocarbon group represented by Y.

The aryl group represented by Z may be the same as those defined for the aryl group represented by Y.

The heterocyclic group represented by Z is not limited for the number of atoms constituting the ring, and it may be either a monocyclic ring or a polycyclic ring containing fused rings, while the monocyclic ring is the preferred. In the case of a monocyclic ring, it may preferably comprise 3 to 10 atoms, more preferably 4 to 8 atoms, and most preferably 5 to 6 atoms. In the case of the group containing fused rings, it may preferably comprise 2 to 6 rings, and more preferably 2 to 3 rings. The heterocyclic group may be either an aromatic or a non-aromatic group. In a preferred embodiment, the heterocyclic group is a five-membered aromatic ring.

The heterocyclic group represented by Z contains at least one hetero atom other than the carbon atom and the hydrogen atom. Exemplary hetero atoms include sulfur atom, oxygen atom, selenium atom, tellurium atom, phosphorus atom, silicon atom, and boron atom.

Examples of the heterocyclic group represented by Z include pyridine ring, pyrazine ring, pyridazine ring, pyrimidine ring, triazine ring, quinoline ring, isoquinoline ring, quinazoline ring, cinnoline ring, phthalazine ring, quinoxaline ring, pyrrole ring, indole ring, furan ring, benzofuran ring, thiophene ring, benzothiophene ring, pyrazole ring, oxazole ring, banzoxazole ring, thiazole ring, benzothiazole ring, isothiazole ring, benzisothiazole ring, thiadiazole ring, isoxazole ring, benzisoxazole ring, pyrrolidine ring, piperidine ring, piperazine ring, imidazolidine ring, and thiazoline ring, and the preferred are pyridine ring, pyrazine ring, pyrimidine ring, triazine ring, furan ring, thiophene ring, and oxazole ring.

Z¹ and Z² in the —NZ¹Z² and Z³ in the —OZ³ represented by Z are independently hydrogen atom, an aliphatic hydrocarbon group, an aryl group, or a heterocyclic group. The aliphatic hydrocarbon group is as defined for the aliphatic hydrocarbon group represented by Y, the aryl group is as defined for the aryl group represented by Y, and the heterocyclic group is as defined for the heterocyclic group represented by X.

A preferred embodiment of the compound represented by the general formula (1) is the one wherein X is tetrazole or triazole, Y is hydrogen atom, Z is —NZ¹Z², Z¹ is hydrogen atom, and Z² is an aliphatic hydrocarbon group substituted by hydroxy group. This compound is preferable in view of reducing the scratches formed during the polishing.

Alternatively, Y and Z may together form a ring.

The compound represented by the general formula (1) may preferably have a molecular weight of 70 to 300, and more preferably 90 to 200. When the molecular weight is in excess of 300, the compound will be less soluble in the polishing slurry whereas the molecular weight less than 70 is less preferable because of the unfavorable dishing. Preferable compounds represented by the general formula (1) include those as listed below which by no means limit the scope of the present invention.

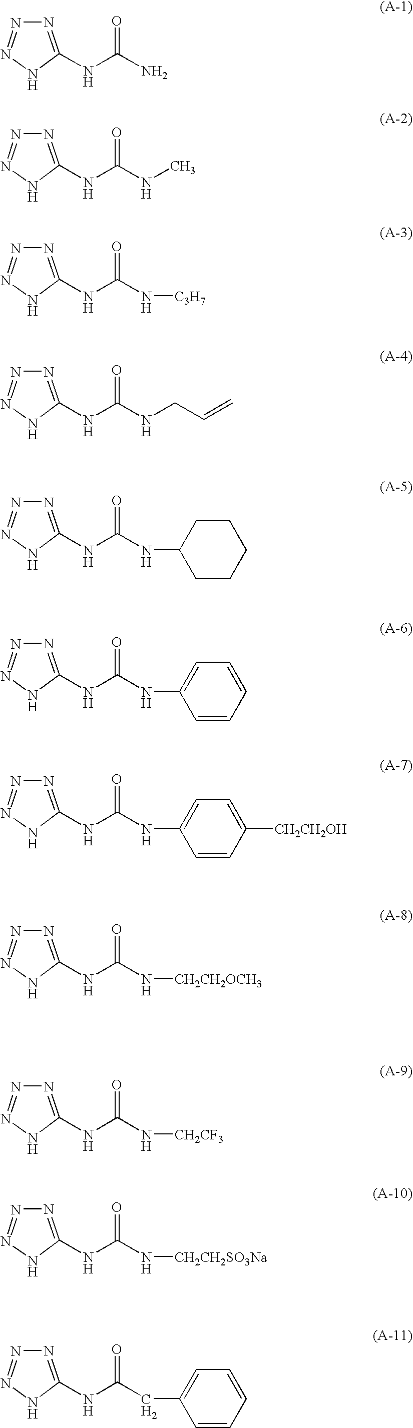

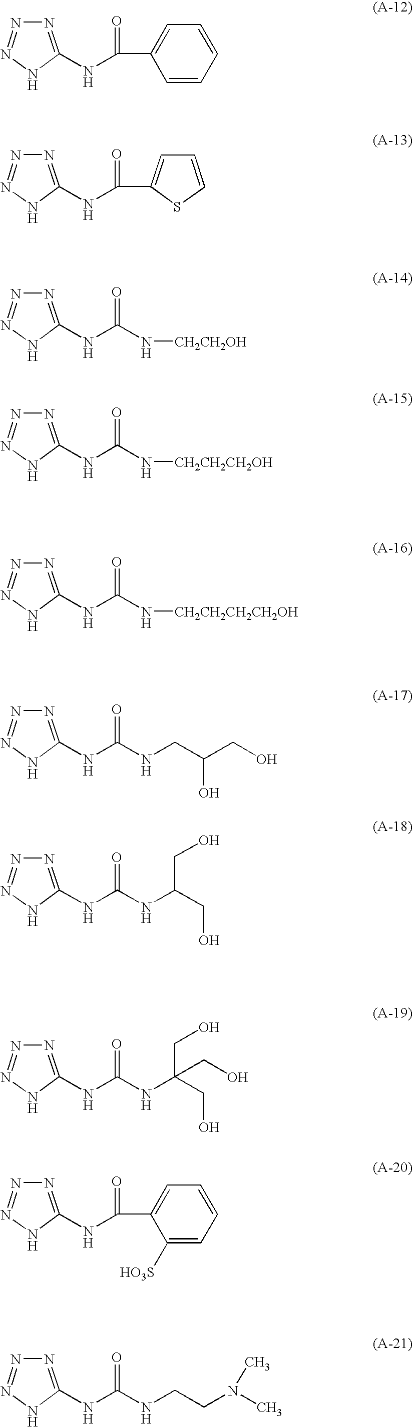

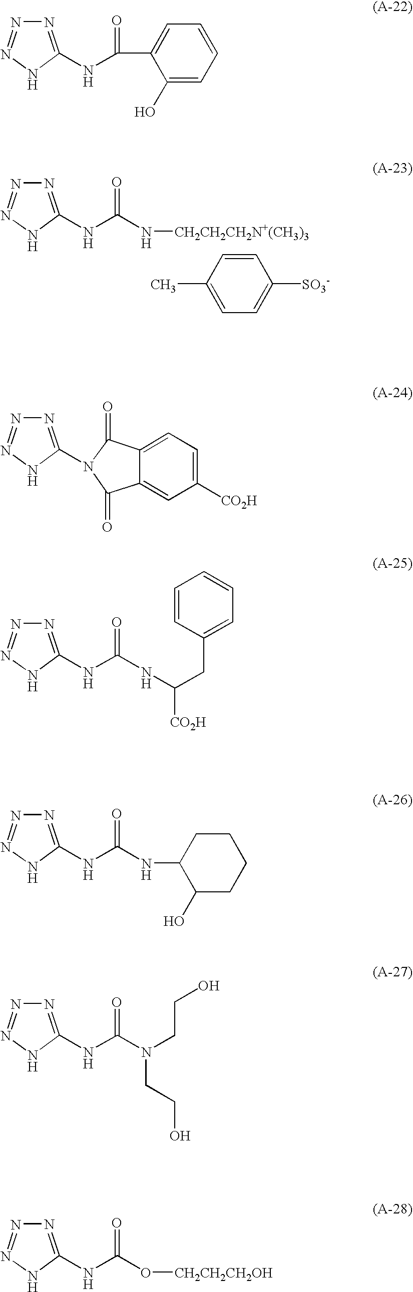

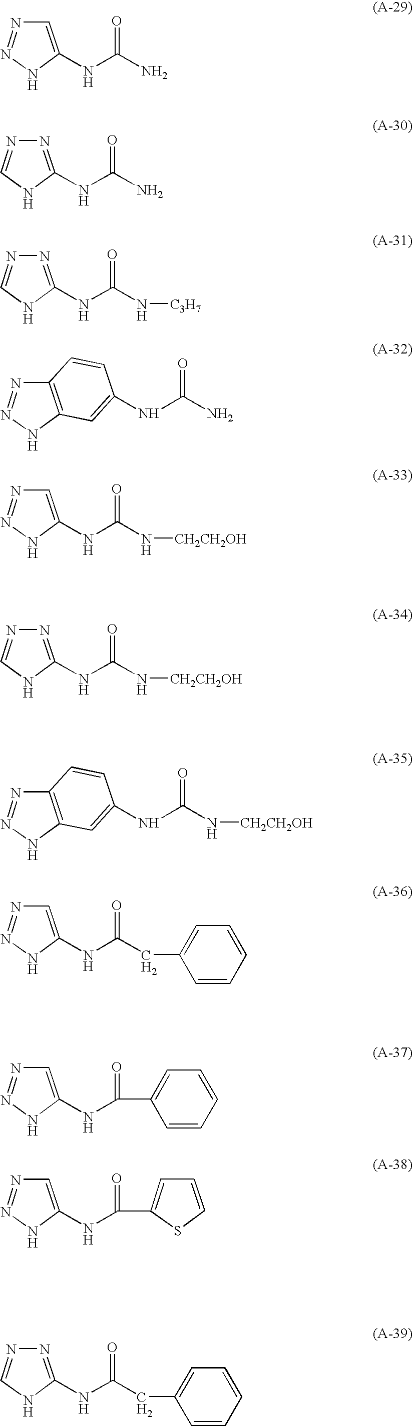

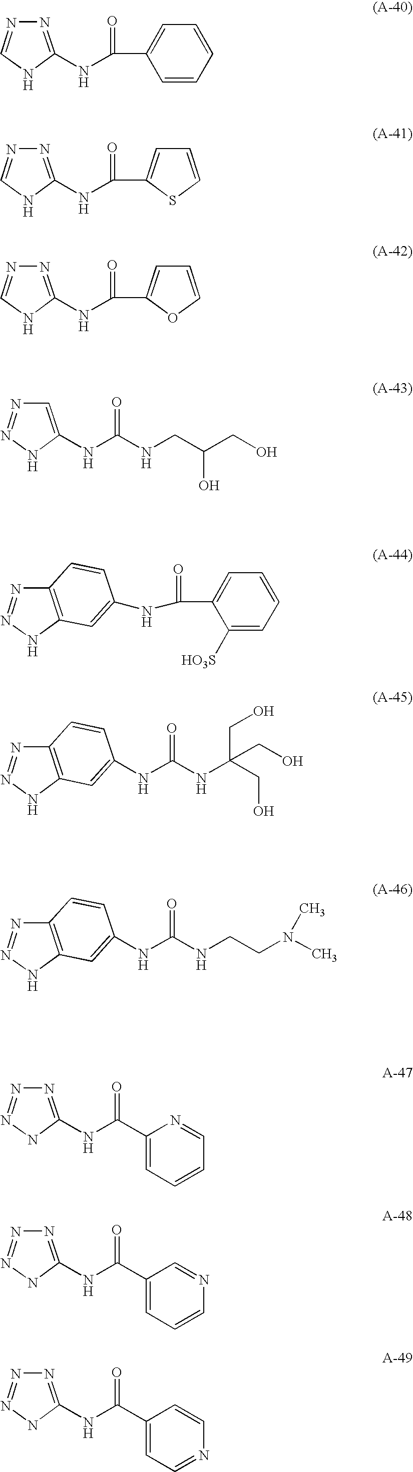

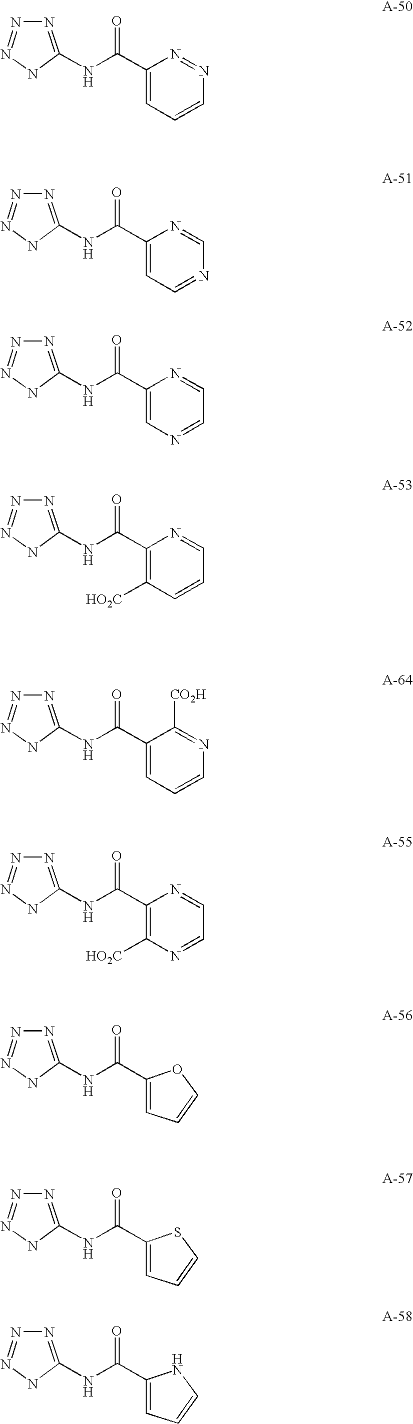

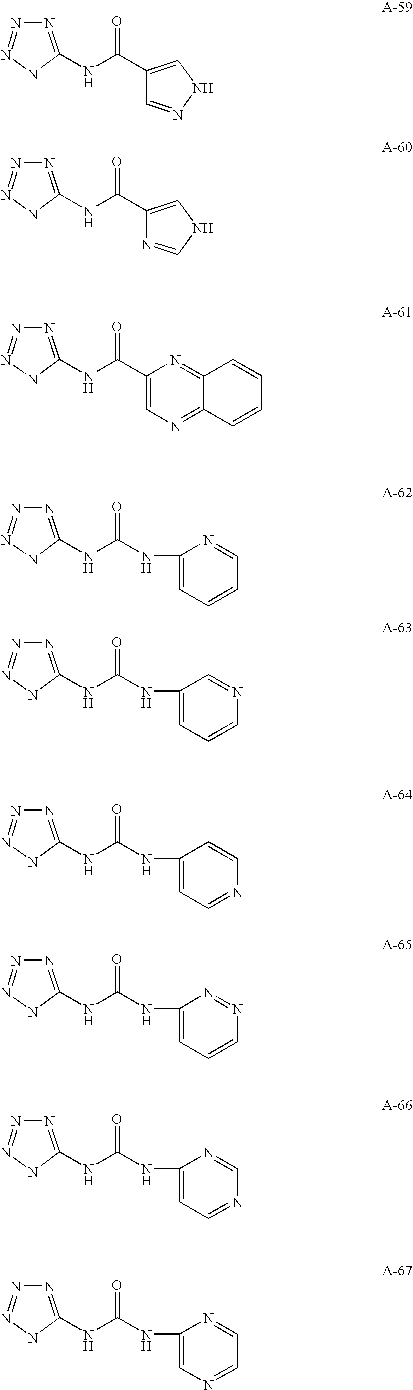

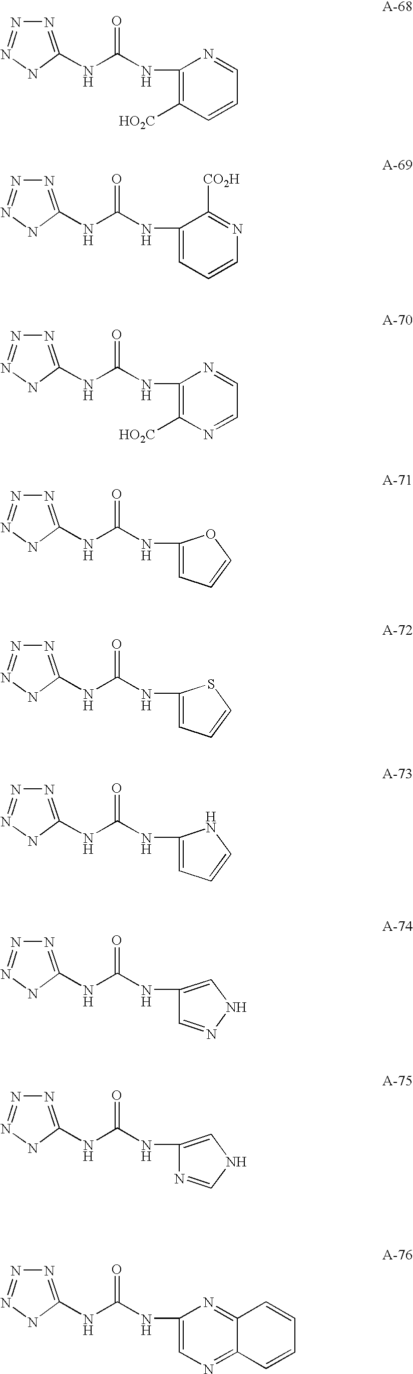

Preferably, the compound represented by the general formula (1) is used in the present invention at a total content of 1×10⁻⁸ to 1×10⁻¹ mol, more preferably at 1×10⁻⁷ to 1×10⁻² mol, and most preferably at 1×10⁻⁶ to 1×10⁻³ mol in relation to 1 L of the metal polishing slurry actually used in the polishing. Use of the compound represented by the general formula (1) at a content in such range is preferable in view of maintaining the high polishing speed.

The metal polishing slurry of the present invention includes both the metal polishing slurry actually used in the polishing (namely, the polishing slurry which has been diluted as necessary), and also, a concentrate of the metal polishing slurry. The term “concentrate” means a polishing slurry which has been prepared to have a higher concentration of the solute than the polishing slurry actually used in the polishing. The concentrate is used for the polishing after diluting the concentrate with water or an aqueous solution. In the dilution, the concentrate is typically diluted to 1 to 20 volumes.

In the present invention, the terms “concentration” and “concentrate” are used in the sense customarily used in the art, namely, when the solution is more “concentrated” or the solution is a “concentrate” having a higher concentration than the polishing slurry actually used in the polishing. In other words, these terms are not used in the general sense involving the physical concentration procedure such as evaporation.

The compound represented by the general formula (1) may be a commercially available product or the one synthesized by a known method such as J. Med. Chem. vol. 27, No. 2, page 125 (1984).

### [Oxidizing Agent]

The metal polishing slurry of the present invention contains a compound which is capable of oxidizing the metal to be polished (oxidizing agent). The oxidizing agent is not particularly limited as long as it is a compound which is capable of oxidizing the metal to be polished, and exemplary such compounds include hydrogen peroxide, peroxides, nitrate salts, iodate salts, periodate salts, hypochlorite salts, chlorite salts, chlorate salts, perchlorate salts, persulfate salts, bichromate salts, permanganate salts, ozone water, silver (II) salts, and iron (III) salts. Among these, the preferred is hydrogen peroxide, and these compounds may be used alone or in combination of two or more.

The oxidizing agent is preferably incorporated at a total amount of 0.003 to 8 mol, more preferably at 0.03 to 6 mol, and most preferably at 0.1 to 4 mol in 1 L of the metal polishing slurry actually used in the polishing. Incorporation of the oxidizing agent at an amount of at least 0.003 mol is preferable for sufficient metal oxidization and high polishing speed, while incorporation at an amount up to 8 mol is preferable for preventing roughening of the polishing surface.

### [Organic Acid]

The metal polishing slurry of the present invention contains an organic acid which is added for its function of facilitating the oxidation, pH adjustment, and buffering. The organic acid is a compound having a structure which is different from the oxidizing agent added for the metal oxidation as described above, and the organic acid does not include the acid which functions as the oxidizing agent. The organic acid is not particularly limited as long as it is an organic compound generating an acid, while the preferred organic acids are those which are soluble in water as in the case of amino acids.

Exemplary amino acids include glycine, L-alanine, β-alanine, N-methylglycine, L-2-aminobutyric acid, L-norvaline, L-valine, L-leucine, L-norleucine, L-isoleucine, L-alloisoleucine, L-phenylalanine, L-proline, L-ornithine, L-lysine, taurine, L-serine, L-threonine, L-allothreonine, L-homoserine, L-tyrosine, 3,5-diiodo-L-tyrosine, dihydroxyethyl glycine, β-(3,4-dihydroxyphenyl)-L-alanine, L-thyroxine, 4-hydroxy-L-proline, L-cysteine, L-methionine, L-ethionine, L-lanthionine, L-cystathionine, L-cystine, L-cysteic acid, L-aspartic acid, L-glutamic acid, S-(carboxymethyl)-L-cysteine, 4-aminobutyric acid, L-asparagine, L-glutamine, azaserine, L-arginine, L-canavanine, L-citrulline, δ-hydroxy-L-lysine, creatine, L-kynurenine, L-histidine, 1-methyl-L-histidine, 3-methyl-L-histidine, ergothioneine, L-tryptophan, actinomycin C1, apamin, angiotensin I, angiotensin II, and antipain, and the preferred are glycine, L-alanine, β-alanine, and N-methylglycine. These amino acids may be used alone or-in combination of two or more.

Examples of the organic acid other than the amino acid include formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, hydroxyethylimino diacetic acid, imino diacetic acid, and ammonium salts, or alkali metal salts of these acids. Among these, the preferred are malic acid, tartaric acid, citric acid, hydroxyethylimino diacetic acid, and imino diacetic acid in view of effectively suppressing the etching speed while maintaining practically acceptable polishing speed.

The organic acid is preferably incorporated at a total amount of 0.0005 to 0.5 mol, preferably at 0.005 to 0.3 mol, and more preferably at 0.01 to 0.1 mol in 1 L of the metal polishing slurry actually used in the polishing. Incorporation of the organic acid at an amount of up to 0.5 mol is preferable for suppressing the etching while incorporation of at least 0.0005 mol is preferable for realizing the sufficient effect.

The metal polishing slurry of the present invention preferably contains an abrasive. Exemplary abrasives include silica (e.g. precipitated silica, fumed silica, colloidal silica, and synthesized silica), ceria, alumina, titania, zirconia, germania, manganese oxide, silicon carbide, polystyrene, polyacryl, and polyterephthalate, and use of colloidal silica is preferable in view of realizing the significant effects of the present invention.

Such abrasive may be produced by a method known in the art or purchased from a commercial source.

The abrasive may preferably have a primary particle size of 5 to 200 nm, more preferably 10 to 70 nm, and most preferably 20 to 50 nm. When the abrasive has a primary particle size within such range, higher polishing speed as well as reduced dishing are realized. The primary particle size of the abrasive used in the present invention is an average particle diameter calculated from the particle size distribution obtained by dynamic light scattering method. An exemplary apparatus used for measuring the particle size distribution is LB-500 manufactured by Horiba.

The abrasive may be partly associated. The average association degree of the abrasive is preferably up to 7, and more preferably up to 3. When the average association degree of the abrasive is within such range, occurrence of the erosion and scratches is suppressed. The average association degree is the value obtained by dividing diameter of the secondary particle produced by aggregation of the primary particles with the diameter of the primary particle (the diameter of the secondary particle/the diameter of the primary particle). Accordingly, when the abrasive has an average association degree of 1, the abrasive solely comprises monodispersed primary particles. The secondary particle size is determined by measuring diameter of at least two secondary particles in the picture image taken by an electron microscope and calculating the average.

The secondary particles formed by the association of the abrasive may preferably have a secondary particle size of up to 100 nm in view of preventing occurrence of the erosion and scratches. The lower limit is preferably at least 20 nm to realize sufficient polishing speed. More preferably, the secondary particle size is in the range of 30 to 50 nm. The abrasive used may also be a commercially available product.

Content of the abrasive in the metal polishing slurry is preferably in the range of 0.05 to 20 g, and more preferably 0.2 to 5 g in 1 L of the metal polishing slurry actually used in the polishing in view of realizing a high polishing speed and reduced dishing.

When the metal polishing slurry contains no abrasive or the abrasive concentration is less than 0.01% by weight, the polishing speed and the dishing properties can be improved by adjusting the pH to the range of at least 3.5, and in particular, to the range of at least 4.0.

In the present invention, the colloidal silica used is preferably a colloidal silica having at least a part of the silicon atoms on its surface modified with aluminum atom. By using such colloidal silica having at least a part of its surface silicon atoms modified with aluminum atom, dishing can be further reduced. The colloidal silica having a part of its surface modified with aluminum atom is the colloidal silica in which aluminum atom is present on the surface of the colloidal silica including the site where the silicon atoms have a coordination number of 4.

In modifying the silicon atom on the surface of the colloidal silica with aluminum atom to produce the predetermined colloidal silica, an aluminate compound such as ammonium aluminate may be added to a dispersion of colloidal silica. In one method, a silica sol obtained by adding an alkaline aqueous solution of aluminate is heated at 80 to 250° C. for 0.5 to 20 hours, and the heated silica sol is contacted with a cation-exchange resin or with a cation-exchange resin and an anion-exchange resin. In another method, an acidic solution of silicic acid and an aqueous solution of an aluminum compound are added to a SiO₂-containing alkaline aqueous solution or a SiO₂-containing aqueous solution of an alkaline metal hydroxide. In another method, an acidic silicate solution containing an aluminum compound is added to a SiO₂-containing alkaline aqueous solution or an aqueous solution of an alkaline metal hydroxide, and the resulting alkaline silica sol containing the aluminum compound is treated by a cation-exchange resin for dealkalization. These methods are described in detail in JP 3463328B and JP 63-123807 A, and their disclosure can be applied to the present invention. In another method, an aluminum alkoxide may be added to the dispersion of colloidal silica. The aluminum alkoxide used in this method is not particularly limited while preferable examples include aluminum isopropoxide, aluminum butoxide, aluminum methoxide, and aluminum ethoxide, and the most preferred is use of aluminum isopropoxide or aluminum butoxide.

Amount of the aluminum atom used for modifying the silicon atom on the surface of the colloidal silica is not particularly limited, and the amount can be adequately regulated by controlling the amount (concentration) of the aluminate compound or the aluminum alkoxide added to the colloidal silica dispersion. The modification by aluminum atom can be confirmed, for example, by measuring zeta electrical potential of the abrasive.

### [Surfacantant]

The metal polishing slurry of the present invention may preferably contain a surfactant represented by the following general formula (2):

R-Ar—O-Ar-SO₃⁻M⁺ General formula (2)

for the purpose of reducing the dishing.

In the general formula (2), R represents an alkyl group preferably containing 8 to 20, more preferably 10 to 20, and most preferably 12 to 20 carbon atoms. The alkyl group represented by R may be either a linear or a branched alkyl group, and preferably a linear alkyl group. Exemplary such alkyl groups include decyl group, undecyl group, dodecyl group, tridecyl group, tetradecyl group, pentadecyl group, hexadecyl group, heptadecyl group, octadecyl group, nonadecyl group, and eicosyl group, and the preferred are dodecyl group, tridecyl group, tetradecyl group, pentadecyl group, octadecyl group, nonadecyl group, and eicosyl group.

In the general formula (2), Ar represents an aryl group. Exemplary aryl groups represented by Ar include phenyl group, naphthyl group, anthryl group, and phenanthryl group, and the preferred is phenyl group. The two Ar groups in the general formula (2) may be either the same or different, and preferably the same.

The alkyl group or the aryl group may be further substituted with a substituent. Exemplary such substituents include halogen atom (fluorine atom, chlorine atom, bromine atom, or iodine atom), alkyl group (a linear, branched, or cyclic alkyl group which may be a polycyclic alkyl group such as a bicycloalkyl group and which may include an active methine group), alkenyl group, alkynyl group, aryl group, heterocyclic group (which is not limited for the position of the substitution), acyl group, alkoxycarbonyl group, aryloxycarbonyl group, heterocyclic oxycarbonyl group, carbamoyl group (which may be substituted as in the case of N-hydroxycarbamoyl group, N-acylcarbamoyl group, N-sulfonylcarbamoyl group, N-carbamoylcarbamoyl group, thiocarbamoyl group, or N-sulfamoylcarbamoyl group), carbazoyl group, carboxy group or its salt, oxalyl group, oxamoyl group, cyano group, carbonimidyl group, formyl group, hydroxy group, alkoxy group (including the group containing repetition of ethylenoxy group or propylenoxy group), aryloxy group, heterocyclic oxy group, acyloxy group, (alkoxy or aryloxy) carbonyloxy group, carbamoyloxy group, sulfonyloxy group, amino group, (alkyl, aryl, or heterocyclic) amino group, acylamino group, sulfonamide group, ureido group, thioureido group, N-hydroxyureido group, imide group, (alkoxy or aryloxy)carbonylamino group, sulfamoylamino group, semicarbazide group, thiosemicarbazide group, hydrazino group, ammonio group, oxamoylamino group, N-(alkyl or aryl)sulfonylureido group, N-acylureido group, N-acylsulfamoylamino group, hydroxy amino group, nitro group, heterocyclic group containing quaternarized nitrogen atom (for example, pyridinio group, imidazolio group, quinolinio group, or isoquinolinio group), isocyano group, imino group, mercapto group, (alkyl, aryl, or heterocyclic) thio group, (alkyl, aryl, or heterocyclic) dithio group, (alkyl or aryl) sulfonyl group, (alkyl or aryl) sulfinyl group, sulfo group, sulfamoyl group (which may be substituted with a substituent as in the case of N-acylsulfamoyl group or N-sulfonylsulfamoyl group), phosphino group, phosphinyl group, phosphinyloxy group, phosphinylamino group, and SILYL group. The preferred are alkyl group and sulfo group.

In the general formula (2), M⁺ represents hydrogen ion, alkali metal ion, or ammonium ion (NH₄⁺). Examples of the alkali metal ion include potassium ion, sodium ion, and lithium ion, and the preferred is sodium ion. The ammonium ion (NH₄⁺) also includes ammonium ion having its hydrogen atom substituted with an alkyl group such as tetramethyl ammonium ion and tetraethyl ammonium ion. Preferably, M⁺ is hydrogen ion or ammonium ion, and more preferably hydrogen ion.

Exemplary surfactants represented by the general formula (2) include alkyl diphenyl ether disulfonic acid such as dodecyl diphenyl ether disulfonic acid, tetradecyl diphenyl ether disulfonic acid, hexadecyl diphenyl ether disulfonic acid, octadecyl diphenyl ether disulfonic acid, and eicosyl diphenyl ether disulfonic acid, or their salt; alkyl diphenyl ether monosulfonic acid such as dodecyl diphenyl ether monosulfonic acid, tetradecyl diphenyl ether monosulfonic acid, hexadecyl diphenyl ether monosulfonic acid, octadecyl monophenyl ether disulfonic acid, and eicosyl monophenyl ether disulfonic acid, or their salt; and dodecyl dinaphthyl ether disulfonic acid, dodecyl dianthryl ether disulfonic acid, dodecyl dinaphthyl ether monosulfonic acid, dodecyl dianthryl ether monosulfonic acid, or their salts. Among these, the preferred are an alkyl diphenyl ether disulfonic acid or its salt, and a mixture of an alkyl diphenyl ether disulfonic acid and an alkyl diphenyl ether monosulfonic acid or a mixture their salts in view of reducing the dishing. In the case of such mixture, the mixture preferably contains at least 10% by mole, preferably at least 30% by mole, and more preferably at least 50% by mole of the alkyl diphenyl ether monosulfonic acid. These surfactants may be used alone or in combination of two or more.

The surfactant represented by the general formula (2) is preferably used at a total content of 0.0001% by weight to 0.1% by weight, more preferably at 0.0005% by weight to 0.05% by weight, and most preferably at 0.001% by weight to 0.01% by weight in relation to the metal polishing slurry used in the polishing. Use at less than 0.0001% by weight only results in the realization of the limited effects while use at a content in excess of 0.1% by weight is uneconomical due to the saturation of the effects.

The method used for synthesizing the surfactant represented by the general formula (2) is not particularly limited, and commercially available surfactant may also be used.

Preferably, the metal polishing slurry of the present invention also contains a surfactant and/or a hydrophilic polymer other than those represented by the general formula (2). Both the surfactant and the hydrophilic polymer have the effect of reducing the contact angle of the surface to be polished which facilitates consistent polishing.

The surfactant and/or the hydrophilic polymer is preferably the one selected from the group as described below, and they may be used alone or in combination of two or more.

Examples of the anionic surfactant include carboxylate salt, sulfonate salt, sulfate salt, and phosphate salt. Exemplary carboxylate salts include soap, N-acylaminoacid salt, polyoxyethylene or polyoxypropylene alkyl ether carboxylate salt, and acylated peptide; sulfonate salts such as alkyl sulfonate salt, alkylbenzene and alkylnaphthalene sulfonate salt, naphthalene sulfonate salt, sulfosuccinate salt, a-olefin sulfonate salt, and N-acylsulfonate salt; sulfate salts such as turkey-red oil, alkyl sulfate salt, alkyl ether sulfate salt, polyoxyethylene or polyoxypropylene alkylallyl ether sulfate salt, and alkylamidosulfate salt; and phosphate salts such as alkyl phosphate salt and polyoxyethylene or polyoxypropylene alkylallyl ether phosphate salt.

Examples of the cationic surfactant include aliphatic amine salt, aliphatic quaternary ammonium salt, benzalkonium chloride salt, benzethonium chloride, pyridinium salt, and imidazolinium salt.

Examples of the amphoteric surfactant include carboxy betaine surfactants, aminocarboxylate salt, imidazolinium betaine, lecithin, and alkylamine oxide.

Examples of the non-ionic surfactant include ether surfactants, ether ester surfactants, ester surfactants, nitrogen-containing surfactants. Exemplary ether surfactants include polyoxyethylene alkyl and alkylphenyl ether, alkylallyl formaldehyde-condensed polyoxyethylene ether, polyoxyethylene polyoxypropylene block polymer, and polyoxyethylene polyoxypropylene alkyl ether. Exemplary ether ester surfactants include polyoxyethylene ether of glycerin ester, polyoxyethylene ether of sorbitan ester, and polyoxyethylene ether of sorbitol ester. Exemplary ester surfactants include polyethyleneglycol fatty acid ester, glycerin ester, polyglycerin ester, sorbitan ester, propylene glycol ester, and sugar ester. Exemplary nitrogen-containing surfactants include fatty acid alkanolamide, polyoxyethylene fatty acid amide, and polyoxyethylene alkylamide.

Other examples include fluorosurfactants.

Other surfactants and hydrophilic polymers include esters such as glycerin ester, sorbitan ester, methoxyacetic acid, ethoxyacetic acid, 3-ethoxypropionic acid, and alanin ethyl ester; polyglycols such as polyethylene glycol, polypropylene glycol, polytetramethylene glycol, polyethylene glycol alkyl ether, polyethylene glycol alkenyl ether, alkyl polyethylene glycol, alkyl polyethylene glycol alkyl ether, alkyl polyethylene glycol alkenyl ether, alkenyl polyethylene glycol, alkenyl polyethylene glycol alkyl ether, alkenyl polyethylene glycol alkenyl ether, polypropylene glycol alkyl ether, polypropylene glycol alkenyl ether, alkyl polypropylene glycol, alkyl polypropylene glycol alkyl ether, alkyl polypropylene glycol alkenyl ether, alkenyl polypropylene glycol, alkenyl polypropylene glycol alkyl ether, and alkenyl polypropylene glycol alkenyl ether; polysaccharides such as alginic acid, pectic acid, carboxymethylcellulose, curdlan, and pullulan; amino acid salts such as glycine ammonium salt and glycine sodium salt; polycarboxylic acids and their-salts such as polyaspartic acid, polyglutamic acid, polylysine, polymalic acid, polymethacrylic acid, poly(ammonium methacrylate), poly(sodium methacrylate), polyamide acid, polymaleic acid, polyitaconic acid, polyfumaric acid, poly (p-styrene carboxylic acid), polyacrylic acid, polyacrylamide, aminopolyacrylamide, poly(ammonium acrylate), poly(sodium acrylate), polyamide acid, ammonium salt of polyamide acid, sodium salt of polyamide acid, and polyglyoxylic acid; vinyl polymers such as polyvinyl alcohol, polyvinylpyrrolidone, and polyacrolein; sulfonic acid and its salts such as ammonium methyltaurate, sodium methyltaurate, sodium methylsulfate, ammonium ethylsulfate, ammonium butylsulfate, sodium vinylsulfate, sodium 1-allylsulfonate, sodium 2-allylsulfonate, sodium methoxymethylsulfonate, ammonium ethoxymethylsulfonate, sodium 3-ethoxypropylsulfonate, sodium methoxymethylsulfonate, sodium 3-ethoxypropylsulfonate, and sodium sulfosuccinate; and amides such as propionamide, acrylamide, methylurea, nicotinamide, succinic amide, and sulphanylamide.

However, when the metal polishing slurry is used for a substrate such as silicon substrate for a semiconductor integrated circuit, use of an acid or its ammonium salt is preferred in view of preventing the contamination by an alkaline metal, alkaline earth metal, or halide. A substrate such as a glass substrate is free from such limitation.

Of the compounds as mentioned above, the preferred are cyclohexanol, poly(ammonium acrylate), polyvinyl alcohol, succinic amide, polyvinylpyrrolidone, polyethylene glycol, and polyoxyethylene polyoxypropylene block polymer.

The surfactant and/or the hydrophilic polymer may preferably have a weight average molecular weight of 500 to 100000, and more preferably 2000 to 50000.

The surfactant and/or the hydrophilic polymer other than those represented by the general formula (2) is preferably incorporated at a total content of 0.0001% by weight to 1.0% by weight, more preferably at 0.0005% by weight to 0.5% by weight, and most preferably at 0.001% by weight to 0.1% by weight in relation to 1 L of the metal polishing slurry actually used for polishing. Incorporation of at least 0.0001% is preferable for realizing the sufficient effect, and incorporation of up to 1.0% by weight is preferable for preventing decrease in the polishing speed.

### [Other Components]

The metal polishing slurry of the present invention may also contain other components such as a heterocyclic compound other than the one represented by the general formula (1), a pH adjusting agent, and other additives.

### [Heterocyclic Compound]

The metal polishing slurry of the present invention may contain a heterocyclic compound other than the one represented by the general formula (1) at a content not adversely affecting the effects of present invention. A heterocyclic compound is a compound having a heterocycle containing at least one hetero atom. Non-limiting exemplary heterocyclic compounds include 1,2,3,4-tetrazole, 5-amino-1,2,3,4-tetrazole, 5-methyl-1,2,3,4-tetrazole, 1,2,3-triazole, 4-amino-1,2,3-triazole, 4,5-diamino-1,2,3-triazole, 1,2,4-triazole, 3-amino-1,2,4-triazole, 3,5-diamino-1,2,4-triazole, and benzotriazole, which may be used alone or in combination of two or more.

### [pH Controlling Agent]

The metal polishing slurry of the present invention may optionally include an acidic agent and an alkaline agent for adjusting the pH, or in addition, a buffering agent for suppressing change in the pH. Exemplary acidic agents include an inorganic acid such as sulfuric acid, nitric acid, boric acid, and phosphoric acid. The preferred is sulfuric acid. Exemplary alkaline agents and buffering agents include non-metallic alkaline agents, for example, ammonia; organic ammonium hydroxide such as ammonium hydroxide or tetramethylammonium hydroxide; alkanol amines such as diethanolamine, triethanolamine, or triisopropanol amine; alkali metal hydroxides such as sodium hydroxide, potassium hydroxide, or lithium hydroxide; carbonate such as sodium carbonate; phosphate such as trisodium phosphate; borate; tetraborate; hydroxybenzoic acid or the like.

Preferred alkaline agents include ammonium hydroxide, potassium hydroxide, lithium hydroxide, and tetramethylammonium hydroxide.

The acidic agent, the alkaline agent, and the buffering agent may be incorporated at an amount capable of maintaining the pH to the preferable range. They are preferably used at 0.0001 to 1.0 mol, and more preferably at 0.003 to 0.5 mol in relation to 1 L of the metal polishing slurry used in the polishing. The pH of the metal polishing slurry actually used for the polishing is preferably in the range of from 3 to 12, more preferably 4 to 9, and still more preferably 5 to 8. The effect of the metal polishing slurry is particularly excellent in this pH range.

### [Chelating Agent]

The metal polishing slurry according to the present invention may contain a chelating agent (i.e. water softener), if necessary, for reducing an adverse effect caused by the contaminant polyvalent metal ions. The chelating agent used may be a versatile water softener which prevents precipitation of calcium and magnesium or a related compounds thereof. Exemplary chelating agents include nitrilotriacetic acid, diethylenetriaminepentaacetic acid, ethylenediaminetetraacetic acid, N,N,N-trimethylene phosphonic acid, ethylenediamine-N,N,N′,N′-tetramethylenesulfonic acid, transcyclohexanediaminetetraacetic acid, 1,2-diaminopropane tetraacetic acid, glycol ether diaminetetraacetic acid, ethylenediamine ortho hydroxy phenyl acetic acid, ethylenediamine disuccinic acid (SS body), N-(2-ethyl carboxylate)-L-aspartic acid, β-alanine diacetic acid, 2-phosphonobutane-1,2,4-tricarboxylic acid, 1-hydroxyethylidene-1,1-diphosphonic acid, N,N′-bis(2-hydroxy benzyl) ethylenediamine-N,N′-diacetic acid, 1,2-dihydroxy benzene-4,6-diphosphonic acid. The agent may be used alone, or in combination of two or more.

The chelating agent may be used at an amount sufficient for capping the metal ion such as the polyvalent metal ion contaminant. For example, the chelating agent may be used at 0.0003 to 0.07 mole in relation to 1 L of the metal polishing slurry actually used for polishing.

### [Solvent]

The metal polishing slurry of the present invention may contain a solvent such as water, an alcohol, an ester, or a nitrile. The preferred is sole use of the water. Amount of the solvent in the metal polishing slurry is not particularly limited, and the solvent may be used at any amount as long as the merit of the present invention is not impaired.

The method used for preparing the metal polishing slurry of the present invention is not particularly limited. In an exemplary method, the compound represented by the general formula (1), water, the oxidizing agent and the organic acid, and the optional components as described above are added to a reaction vessel, and the mixture is then thoroughly stirred by using an agitator such as a blender. In this method, each component may be adjusted to the predetermined pH before the mixing, or the pH may be adjusted after the mixing.

Next, the subject to be polished by the metal polishing slurry of the present invention (the subject to be polished) and the polishing method are described in detail.

### [Substrate (Wafer) and Metal Wiring Material]

The subject which is polished by using the metal polishing slurry of the present invention is a substrate (wafer) having a copper wiring, and in particular, a substrate having a wiring comprising copper and/or a copper alloy. The substrate is not particularly limited, and exemplary substrates include silicon wafers and SOI wafers for semiconductors preferably having a diameter of at least 200 mm, and more preferably at least 300 mm in view of the remarkable effects realized when used in combination with the metal polishing slurry of the present invention.

A copper alloy including silver is suitable as the metal wiring material among the copper alloys. The content of silver in the copper alloy is preferably up to 10% by weight, more preferably up to 1% by weight, and more preferably in the range of 0.00001 to 0.1% by weight in view of fully exerting the advantages of the metal polishing slurry of the present invention.

### [Width of Interconnects]

In the present invention, the interconnections of the substrate subjected to the polishing has a half pitch of, in DRAM devices, for example, preferably up to 0.15 μm, more preferably up to 0.10 μm, and even more preferably up to 0.08 μm. In microprocessing unit (MPU) devices, the half pitch is preferably up to 0.12 μm, more preferably up to 0.09 μm, and even more preferably up to 0.07 μm. The metal polishing slurry of the invention produces a particularly good result on those having such interconnections.

### [Metallic Barrier Material]

In the present invention, the substrate subjected to the polishing preferably has a barrier layer formed between copper and/or copper alloy wiring and an insulating film (including the interlayer dielectric film) for preventing the diffusion of copper. The barrier layer is preferably formed from a low-resistance metal material such as TiN, TiW, Ta, TaN, W, or WN, and more preferably, from Ta or TaN.

### [Interlayer Dielectric Film]

The interlayer dielectric film is preferably the one having a low dielectric constant, and the preferably, the insulator substance is the one having a relative dielectric constant of up to 3.0, and more preferably up to 2.5.

### [Polishing Method (Chemical Mechanical Polishing (CMP))]

The chemical mechanical polishing method of the present invention is a polishing method which involves supplying the metal polishing slurry of the present invention to the polishing pad on the platen, and bringing the polishing pad into contact with the surface to be polished, and carrying out polishing by moving the surface to be polished and the polishing pad relatively to each other.

### [Polishing Apparatus]

The polishing apparatus used in the present invention may be an ordinary polisher having a holder which holds the subject to be polished (such as semiconductor integrated circuit substrate or the like) having a surface to be polished and a platen (provided with a motor whose number of revolution is variable or the like) onto which a polishing pad is attached. An exemplary polishing apparatus is FREX300 manufactured by Ebara Corporation.

### [Polishing Pad]

The polishing pad is not particularly limited, and it may be a pad having a non-foamed structure or a pad having a foamed structure. The pad having a non-foamed structure typically comprises a hard synthetic resin bulk material such as a plastic plate. The pad having a foamed structure is categorized into three types, namely, those made of closed-cell foam (dry expanded), those made of interconnected-cell foam (wet expanded), and those made of two-layer composites (laminated). Of these, pads made of two-layer composites (laminated) are especially preferred. The foaming may be uniform or non-uniform. In addition, the polishing pad may contain the abrasive used in the polishing (for example, ceria, silica, alumina, or resin). The polishing pad may be either a soft or a hard pad, and in the case of a laminated polishing pad, the pad may comprise layers each having different hardness. Preferable materials used for the polishing pad include nonwoven fabric, synthetic leather, polyamide, polyurethane, polyester, and polycarbonate. It may have grid of grooves, holes, or concentric or spiral grooves formed in the surface which contacts the surface to be polished.

### [Polishing Pressure]

In the polishing method of the present invention, the suitable polishing pressure, namely, contact pressure between the surface to be polished and polishing pad depends on the apparatus used for the polishing and the composition of the metal polishing slurry. However, the polishing pressure is preferably in the range of from 3,000 to 25,000 Pa, and more preferably 6,500 to 14,000 Pa. Use of the polishing pressure within such range allows improvement of the uniformity throughout the wafer surface and pattern flatness while maintaining high polishing speed.

### [Rotation Speed of Polishing Platen]

Optimal rotation speed of the polishing platen in the present invention depends on the apparatus used for the polishing and the composition of the metal polishing slurry. However, the rotation speed is preferably in the range of 50 to 200 rpm, and more preferably 60 to 150 rpm since use of the rotation speed within such range allows improvement of the uniformity throughout the wafer surface and pattern flatness while maintaining high polishing speed. The polishing head having the polishing pad attached thereto may also be rotated at a rotation speed within suitable range by considering the apparatus used for the polishing and the composition of the metal polishing slurry.

### [Feeding of the Polishing Slurry]

Preferably, the metal polishing slurry is continuously supplied to the polishing pad with a pump during the polishing. While the amount of the polishing slurry supplied to the polishing pad is not limited, it is preferable that the surface of the polishing pad is steadily covered with the polishing slurry. Preferably, the metal polishing slurry is supplied at 50 to 500 ml/min, and more preferably at 100 to 300 ml/min in order to realize high polishing speed and improve uniformity throughout the wafer surface.

The method used for supplying the metal polishing slurry of the present invention is not particularly limited. The metal polishing slurry may be supplied (1) as a concentrate to be diluted with water or an aqueous solution to prepare the polishing slurry actually used in the polishing, (2) as aqueous solutions of each component as described below which are to be mixed and optionally diluted with water to prepare the polishing slurry actually used in the polishing, or (3) as the polishing slurry actually used in the polishing.

A typical method used for diluting the slurry concentrate with the water or the aqueous solution is a method in which a pipe which feeds the metal polishing slurry concentrate and a pipe which feeds the water or the aqueous solution are joined so that the resulting metal polishing slurry which has been mixed and diluted could be supplied to the polishing pad as a slurry which is actually used in the polishing. The mixing of the concentrate with the water or the aqueous solution may be accomplished, for example, by a method in which a pressure is applied to the fluids passing through narrow flow paths so that they collide with each other to become mixed with each other; a method in which a filler such as glass tubing is packed in the pipe to repetitively split and integrate the liquid flow; or a method in which blades which are rotatable by power are provided in the pipe.

Another method is a process in which a pipe for supplying the metal polishing slurry and a pipe for supplying the water or the aqueous solution are provided, and predetermined amount of the fluids are supplied from each pipe to the polishing pad so as to carry out the mixing of the two fluids and the polishing by the relative movement between the polishing pad and the surface to be polished. In another process, a predetermined amount of the metal polishing slurry concentrate and the water or the aqueous solution are added to a single vessel so that they are mixed and diluted to the predetermined concentration, and the slurry after such mixing is supplied to the polishing pad to carry out the polishing.

In another polishing method, the ingredients to be contained in the metal polishing slurry are separated into at least two components. At the time of their use, the two or more components are diluted with water or an aqueous solution, fed to the polishing pad on the platen and brought into contact with the surface to be polished, and polishing is carried out by moving the surface to be polished and the polishing pad relatively to each other. In such case, the ingredients are preferably fed by separating into the component including the oxidizing agent and the component including the organic acid.

For example, the oxidizer may be included in component (A), and the compound represented by the general formula (1), an organic acid, an abrasive, the surfactant represented by the general formula (2), a heterocyclic compound other than the one represented by the general formula (1), other additives, and water may be included in component (B), and these components (A) and (B) may be diluted before its use with water or an aqueous solution. In such case, three pipes are required to separately feed the component (A), the component (B), and the water or the aqueous solution. The dilution by the mixing may be carried out by joining the three pipes in the downstream and feeding the slurry from the integrated pipe to the polishing pad so that the mixing takes place in the integrated part of the pipe. In this case, two pipes may be joined before joining the remaining pipe, and more specifically, the component containing the less soluble additives is initially mixed with other components to thereby ensure sufficient distance and time for the mixing. The pipe of the water or the aqueous solution may be joined in the downstream.

Other exemplary mixing methods include a method in which the three pipes are directly directed to the polishing pad and mixing is accomplished by the relative movement of the polishing pad and the surface to be polished as well as a method in which the three components are mixed in a single vessel, and the diluted metal polishing slurry (the slurry actually used in the polishing) is supplied to the polishing pad.

The metal polishing slurry is used for the polishing typically at a temperature of 10 to 70° C., preferably at 20 to 60° C., and more preferably at 30 to 50° C. Use at a temperature in excess of 70° C. is associated with the risk of decomposition of the oxidizing agent and poor dishing. The temperature lower than 10° C. will result in the reduced polishing speed.

In the polishing method as described above, an alternative procedure is the one in which at least one component including the oxidizing agent is kept at a temperature of up to 40° C. while heating other components to a temperature in the range of room temperature to 100° C., and the temperature is adjusted to a temperature of up to 40° C. by the mixing of the at least one component and other components, or in the subsequent dilution of the mixture with water or an aqueous solution.

As described above, the metal polishing slurry of the invention can be used at a high polishing speed. When the polishing is carried out by using the metal polishing slurry of the present invention, dishing can be reduced and the planarity of the substrate can be improved, thereby making it possible to minimize the occurrence of defects such as corrosion, scratching, thinning, and erosion in the LSI.

### EXAMPLES

Next, the present invention is described in further detail by referring to the Examples, which by no means limit the scope of the invention.

### Synthetic Example 1

### Synthesis of Exemplary Compound A-14

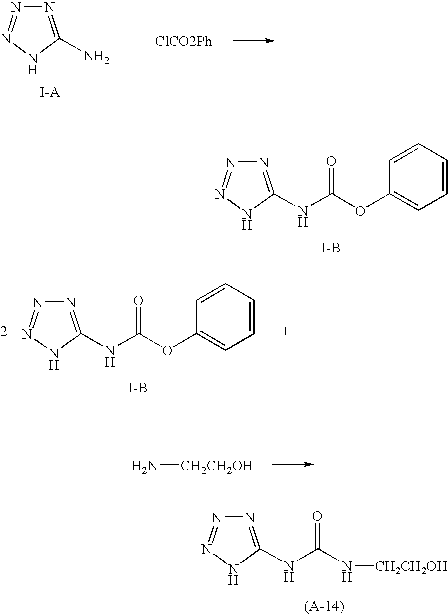

5-aminotetrazole (I-A) (8.5 g, manufactured by Tokyo Chemical Industry Co., Ltd.) was dissolved in N-methylpyrrolidone (200 ml), and to this solution in an ice bath, phenyl chlorocarbonate (17.1 g) was gradually added dropwise. After heating the reaction mixture to 40° C. and stirring for 2 hours, the reaction mixture was added to 2 L ice water with stirring. The precipitate was separated by suction filtration, and washed by adding water (1 L). The separated filtrate was dried to obtain I-B (18.3 g). The thus obtained I-B (10.0 g) was dissolved in acetonitrile (100 ml), and after adding 2-aminoethanol (3.0 g), the mixture was stirred at 60° C. for 2 hours. After concentrating the reaction mixture, methanol (30 ml) was added, and the insoluble content was separated by suction filtration. The filtrate was recrystallized with methanol to obtain A-14 (6.2 g).

Other compounds were synthesized by the corresponding procedures.

### Examples 1 to 33 and Comparative Examples 1 to 6

Polishing slurry Nos. 101 to 133 and 201 to 206 shown in Table 1, below were prepared for evaluation by polishing test. The number of the compounds of the present invention used for the preparation of the polishing slurry corresponds to the number of the compounds represented by the general formula (1) as described above.

### (Preparation of Metal Polishing Slurry)

Each metal polishing slurry was prepared by mixing the following ingredients.

| | | | |
|---|---|---|---|
| (1) | the compound of the invention: the compound | 1.5 | mmol/L |
| | shown in Table 1 | | |
| (2) | organic acid: the compound shown in Table 1 | 0.26 | mol/L |
| (3) | abrasive: the compound shown in Table 1 | 3.2 | g/L |
| (4) | surfactant: the compound shown in Table 1 | 0.01 | g/L |
| (5) | oxidizing agent: hydrogen peroxide | 12.5 | g/L |

Pure water was added to make up for the total volume of 1000 mL, and the pH was adjusted with ammonia solution to pH 7.0.

Commercially available colloidal silica was used in all Examples. The colloidal silica had a primary particle size (simply referred to as “particle size” in the table) of 20 to 70 nm.

The compound used as Comparative Compound 1 in Table 1 is the one represented by the following formula:

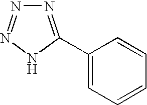

The compound used as Comparative Compound 2 is the one represented by the following formula:

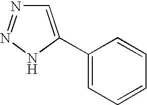

### (Polishing Test)

Polishing was conducted under the following conditions to evaluate the polishing speed and the dishing.

Polisher: FREX 300 (manufactured by Ebara Corporation)

Polishing object (wafer):

(1) The wafer for evaluating the polishing speed: a blanket wafer having a diameter of 300 mm prepared by forming a Cu film having a thickness of 1.5 μm on a silicon substrate

(2) The wafer for evaluating the dishing: copper wiring wafer having a diameter of 300 mm (patterned wafer: mask pattern 754 CMP manufactured by ATDF)

Polishing pad: IC1400-K Groove (manufactured by Rodel)

Polishing condition:

Polishing pressure (contact pressure between the surface to be polished and the polishing pad): 14,000 Pa

Feed speed of the polishing slurry: 200 ml/min

Rotation speed of polishing platen: 104 rpm

Rotation speed of polishing head: 85 rpm

### (Evaluation Method)

Calculation of the polishing speed: The blanket wafer of (1) was polished for 60 seconds, and thickness of the metal film before and after polishing was determined from the electrical resistance at evenly distributed 49 locations on the surface of the wafer. The average value of the thickness change divided by the polishing time was defined as the polishing speed.

Evaluation of dishing: The patterned wafer of (2) was polished for the time period required for completely removing the copper of non-wiring portions by polishing plus 25% excess time. The step height of line-and-space portions (line 10 μm, space 10 μm) was measured by using a contact step height meter DEKTAK V3201 manufactured by Veeco Co.

The polished copper film was evaluated by counting the number of defects in the entire polished area using a wafer inspection apparatus (ComPLUS manufactured by Applied Materials). Next, 200 defects were randomly chosen from the defects detected by the wafer inspection apparatus, and scratches were counted in these 200 defects. The number of scratches (scratch count) in the entire wafer surface was estimated by the following equation.

Scratch count (count/surface)=Number of all defects detected by the wafer inspection apparatus (count/surface)×{(number of the defects which were the scratches in the 200 chosen defects)/200}

The results of the evaluation are shown in Table 1.

TABLE 1

| | Polishing slurry | | | | | | | |
|---|---|---|---|---|---|---|---|---|
| | | | | Abrasive (Particle | | Results of evaluation | | |
| | | General formula | Organic | size, average | | Polishing speed | Dishing | Scratch count |
| | Type | (1) | acid | association degree) | Surfactant | (angstrom/min) | (angstrom) | (Count/surface) |
| Ex. 1 | 101 | Compound A-1 of | Glycine | Colloidal silica | Newcol 220L | 7800 | 450 | 24 |
| | | the invention | | (40 nm, 2) | | | | |
| Ex. 2 | 102 | Compound A-3 of | Glycine | Colloidal silica | Newcol 220L | 6950 | 620 | 53 |
| | | the invention | | (40 nm, 2) | | | | |
| Ex. 3 | 103 | Compound A-11 of | Glycine | Colloidal silica | Newcol 220L | 7200 | 550 | 42 |
| | | the invention | | (40 nm, 2) | | | | |
| Ex. 4 | 104 | Compound A-13 of | Glycine | Colloidal silica | Newcol 220L | 6950 | 580 | 47 |
| | | the invention | | (40 nm, 2) | | | | |
| Ex. 5 | 105 | Compound A-14 of | Glycine | Colloidal silica | Newcol 220L | 7850 | 350 | 16 |
| | | the invention | | (40 nm, 2) | | | | |
| Ex. 6 | 106 | Compound A-14 of | Glycine | Colloidal silica | PELEX SS-L | 7750 | 320 | 15 |
| | | the invention | | (40 nm, 2) | | | | |
| Ex. 7 | 107 | Compound A-14 of | α-alanine | Colloidal silica | NEOPELEX | 7550 | 340 | 15 |
| | | the invention | | (40 nm, 2) | No. 6 | | | |
| Ex. 8 | 108 | Compound A-14 of | N-Methyl- | Colloidal silica | ELEMINOL | 7500 | 320 | 14 |
| | | the invention | glycine | (20 nm, 1) | MON | | | |
| Ex. 9 | 109 | Compound A-14 of | N-Methyl- | Colloidal silica | ELEMINOL | 7600 | 315 | 13 |
| | | the invention | glycine | (20 nm, 2) | MON | | | |
| Ex. 10 | 110 | Compound A-14 of | N-Methyl- | Colloidal silica | ELEMINOL | 7100 | 355 | 27 |
| | | the invention | glycine | (70 nm, 2) | MON | | | |
| Ex. 11 | 111 | Compound A-17 of | Glycine | Colloidal silica | DOWFAX 2A-1 | 7650 | 330 | 13 |
| | | the invention | | (30 nm, 1) | | | | |
| Ex. 12 | 112 | Compound A-17 of | Glycine | Colloidal silica | NEOPELEX | 7800 | 350 | 18 |
| | | the invention | | (30 nm, 1) | No. 6 | | | |
| Ex. 13 | 113 | Compound A-17 of | Glycine | Colloidal silica | Newcol 220L | 7900 | 340 | 15 |
| | | the invention | | (30 nm, 1) | | | | |
| Ex. 14 | 114 | Compound A-17 of | Glycine | Colloidal silica | Pionine A- | 8100 | 290 | 12 |
| | | the invention | | (30 nm, 1) | 43S | | | |
| Ex. 15 | 115 | Compound A-17 of | Glycine | Colloidal silica | — | 7900 | 610 | 45 |
| | | the invention | | (30 nm, 1) | | | | |
| Ex. 16 | 116 | Compound A-17 of | Oxalic acid | Colloidal silica | NEOPELEX | 6950 | 600 | 53 |
| | | the invention | | (30 nm, 1) | No. 6 | | | |
| Ex. 17 | 117 | Compound A-19 of | α-alanine | Colloidal silica | Pionine A- | 7550 | 330 | 13 |
| | | the invention | | (20 nm, 2) | 43-N | | | |
| Ex. 18 | 118 | Compound A-19 of | N-Methyl- | Colloidal silica | Pionine A- | 7600 | 310 | 13 |
| | | the invention | glycine | (30 nm, 2) | 43S | | | |
| Ex. 19 | 119 | Compound A-19 of | N-Methyl- | Colloidal silica | Pionine A- | 7100 | 380 | 26 |
| | | the invention | glycine | (70 nm, 2) | 43S | | | |
| Ex. 20 | 120 | Compound A-19 of | Hydroxy- | Colloidal silica | Pionine A-41 | 7650 | 310 | 15 |
| | | the invention | ethylglycine | (40 nm, 1) | | | | |
| Ex. 21 | 121 | Compound A-19 of | Dihydroxy- | Colloidal silica | PELEX SS-L | 7700 | 305 | 13 |
| | | the invention | ethylglycine | (40 nm, 2) | | | | |
| Ex. 22 | 122 | Compound A-20 of | Glycine | Colloidal silica | Newcol 220L | 7600 | 420 | 25 |
| | | the invention | | (40 nm, 2) | | | | |
| Ex. 23 | 123 | Compound A-20 of | Dihydroxy- | Colloidal silica | PELEX SS-L | 7550 | 370 | 21 |
| | | the invention | ethylglycine | (40 nm, 2) | | | | |
| Ex. 24 | 124 | Compound A-21 of | α-alanine | Colloidal silica | Pionine A- | 7750 | 390 | 14 |
| | | the invention | | (20 nm, 2) | 43-N | | | |
| Ex. 25 | 125 | Compound A-23 of | α-alanine | Colloidal silica | Pionine A- | 7850 | 410 | 13 |
| | | the invention | | (20 nm, 2) | 43-N | | | |
| Ex. 26 | 126 | Compound A-25 of | Glycine | Colloidal silica | Newcol 220L | 7050 | 450 | 29 |
| | | the invention | | (40 nm, 2) | | | | |
| Ex. 27 | 127 | Compound A-33 of | Glycine | Colloidal silica | Newcol 220L | 7550 | 390 | 28 |
| | | the invention | | (40 nm, 2) | | | | |
| Ex. 28 | 128 | Compound A-33 of | N-Methyl- | Colloidal silica | ELEMINOL | 7100 | 420 | 34 |
| | | the invention | glycine | (20 nm, 1) | MON | | | |
| Ex. 29 | 129 | Compound A-34 of | Glycine | Colloidal silica | Newcol 220L | 7650 | 380 | 26 |
| | | the invention | | (40 nm, 2) | | | | |
| Ex. 30 | 130 | Compound A-34 of | N-Methyl- | Colloidal silica | ELEMINOL | 7400 | 410 | 22 |
| | | the invention | glycine | (20 nm, 1) | MON | | | |
| Ex. 31 | 131 | Compound A-43 of | Glycine | Colloidal silica | PELEX SS-L | 7700 | 390 | 32 |
| | | the invention | | (40 nm, 2) | | | | |
| Ex. 32 | 132 | Compound A-43 of | α-alanine | Colloidal silica | Pionine A- | 7600 | 360 | 29 |
| | | the invention | | (20 nm, 2) | 43-N | | | |
| Ex. 33 | 133 | Compound A-43 of | Dihydroxy- | Colloidal silica | PELEX SS-L | 7100 | 410 | 35 |
| | | the invention | ethylglycine | (40 nm, 2) | | | | |
| Comp. | 201 | Comparative | Glycine | Colloidal silica | PELEX SS-L | 5900 | 780 | 142 |
| Ex. 1 | | Compound 1 | | (40 nm, 2) | | | | |
| Comp. | 202 | Comparative | α-alanine | Colloidal silica | NEOPELEX | 5550 | 750 | 163 |
| Ex. 2 | | Compound 1 | | (40 nm, 2) | No. 6 | | | |
| Comp. | 203 | Comparative | Hydroxy- | Colloidal silica | Pionine A-41 | 5450 | 700 | 109 |
| Ex. 3 | | Compound 1 | ethylglycine | (40 nm, 1) | | | | |
| Comp. | 204 | Comparative | Glycine | Colloidal silica | PELEX SS-L | 4550 | 780 | 142 |
| Ex. 4 | | Compound 2 | | (40 nm, 2) | | | | |
| Comp. | 205 | Comparative | α-alanine | Colloidal silica | Pionine A- | 4350 | 750 | 163 |
| Ex. 5 | | Compound 2 | | (20 nm, 2) | 43-N | | | |
| Comp. | 206 | Comparative | Dihydroxy- | Colloidal silica | PELEX SS-L | 4100 | 700 | 109 |
| Ex. 6 | | Compound 2 | ethylglycine | (40 nm, 2) | | | | |

Newcol 220L: sodium dodecylbenzene sulfonate manufactured by Nippon Nyukazai Co., Ltd.
PELEX SS-L: sodium alkyl diphenyl ether disulfonate manufactured by Kao Corporation
NEOPELEX No. 6: dodecylbenzene sulfonate manufactured by Kao Corporation
ELEMINOL MON: sodium dodecylalkyl diphenyl ether disulfonate manufactured by Sanyo Chemical Industries, Ltd.
DOWFAX 2A-1: sodium dodecylalkyl diphenyl ether disulfonate manufactured by DOW
Pionine A-43S: sodium dodecyl diphenyl ether disulfonate manufactured by Takemoto Oil and Fat Co., Ltd.
Pionine A-43-N: ammonium dodecyl alkyl diphenyl ether disulfonate manufactured by Takemoto Oil and Fat Co., Ltd.
Pionine A-41: dodecylbenzene sulfonate manufactured by Takemoto Oil and Fat Co., Ltd.

As demonstrated in Table 1, high polishing speed and reduced dishing could be simultaneously realized by the chemical mechanical polishing method using the metal polishing slurry of the present invention. The scratch count was also low, and the superiority of the compound of the present invention was thereby confirmed.

The advantage of the present invention was particularly significant when the surfactant used was dodecyl diphenyl ether disulfonate, when the organic acid was an amino acid, and when the abrasive had a particle size of 20 to 40 nm.

### Examples 34 to 56 and Comparative Examples 7 to 12

Polishing slurry Nos. 134 to 151 and 207 to 212 shown in Tables 2(1) to 2(3), below were prepared for evaluation by polishing test. The number of the compounds of the present invention used for the preparation of the polishing slurry corresponds to the number of the compounds represented by the general formula (1) as described above.

Each metal polishing slurry was prepared by mixing the following ingredients.

| | | |
|---|---|---|
| the compound of the invention: the compound shown in | 1.5 | mmol/L |
| Table 2 | | |
| organic acid: the compound shown in Table 2 | 0.26 | mol/L |
| abrasive: the compound shown in Table 2 | 3.2 | g/L |
| surfactant: the compound shown in Table 2 | 0.01 | g/L |
| oxidizing agent: hydrogen peroxide | 12.5 | g/L |

Pure water was added to make up for the total volume of 1000 mL, and the pH was adjusted with ammonia solution to pH 7.0.

Commercially available colloidal silica was used in all Examples. The colloidal silica had a primary particle size (simply referred to as “particle size” in the table) of 20 to 70 nm.

### (Polishing Test 2)

Polishing was conducted under the following conditions to evaluate the polishing speed and the dishing.

Polisher: Reflexion (manufactured by Applied Materials)

Polishing object (wafer):

(1) The wafer for evaluating the polishing speed: a blanket wafer having a diameter of 300 mm prepared by forming a Cu film having a thickness of 1.5 μm on a silicon substrate

(2) The wafer for evaluating the dishing: copper wiring wafer having a diameter of 300 mm (patterned wafer: mask pattern 754 CMP manufactured by ATDF)

Polishing pad: IC1010 (manufactured by Rodel)

Polishing condition:

Polishing pressure (contact pressure between the surface to be polished and the polishing pad): 7000 Pa

Feed speed of the polishing slurry: 200 ml/min

Rotation speed of polishing platen: 110 rpm

Rotation speed of polishing head: 100 rpm

Polishing method: In this polishing test, the patterned wafer (2) was polished by a polishing method comprising first and second polishing steps:

first polishing step: the step of polishing a conductor film of copper or copper alloy to the residual thickness of 2000 angstrom,

second polishing step: the step of polishing for the time period required for completely removing the copper of the non-wiring portions by polishing plus 25% excess time

### (Evaluation Method)

Calculation of the polishing speed: The blanket wafer in (1) was polished for 60 seconds, and thickness of the metal film before and after polishing was determined from the electrical resistance at evenly distributed 49 locations on the surface of the wafer. The average value of the thickness change divided by the polishing time was defined as the polishing speed.

Evaluation of step height: The patterned wafer in (2) was polished until the residual thickness of the copper was 2000 angstrom. The step height of line-and-space portions (line 10 μm, space 10 μm) was measured with a contact step height meter DEKTAK V3201 manufactured by Veeco Co.

Evaluation of dishing: The patterned wafer in (2) was polished for a time period of the time required for completely polishing copper of non-wiring portions plus 25% excess of the above-mentioned polishing time. The step height of line-and-space portions (line 10 μm, space 10 μm) was measured with a contact step height meter DEKTAK V3201 manufactured by Veeco Co.

Evaluation of scratch count: The polished copper film was evaluated by counting the number of defects in the entire polished area using a wafer inspection apparatus (ComPLUS manufactured by Applied Materials). Next, 200 defects were randomly chosen from the defects detected by the wafer inspection apparatus, and scratches were counted in these 200 defects. The number of scratches (scratch count) in the entire wafer surface was estimated by the following equation.

Scratch count (count/surface)=Number of all defects detected by the wafer inspection apparatus (count/surface)×{(number of the defects which were the scratch in the 200 chosen defects)/200}

The results of the evaluation are shown in Table 2.

TABLE 2

| | Polishing slurry | | | | | Results of evaluation | | | | |
|---|---|---|---|---|---|---|---|---|---|---|
| | | | | Abrasive | | First polishing step | | Second polishing step | | |
| | | | | (Particle size, | | Polishing | | Polishing | | Scratch |
| | | | | average | | speed | Step | speed | | count |
| | | | | association | | (angstrom/ | height | (angstrom/ | Dishing | (Count/ |
| | Type | General formula (1) | Organic acid | degree) | Surfactant | min) | (angstrom) | min) | (angstrom) | surface) |
| Ex. | 101 | Compound A-1 of | Glycine | Colloidal silica | Newcol | 7800 | 250 | 5600 | 350 | 20 |
| 34 | | the invention | | (40 nm, 2) | 220L | | | | | |
| Ex. | 102 | Compound A-3 of | Glycine | Colloidal silica | Newcol | 6950 | 180 | 5500 | 370 | 18 |
| 35 | | the invention | | (40 nm, 2) | 220L | | | | | |
| Ex. | 103 | Compound A-11 | Glycine | Colloidal silica | Newcol | 7200 | 320 | 5450 | 320 | 18 |
| 36 | | of the | | (40 nm, 2) | 220L | | | | | |
| | | invention | | | | | | | | |
| Ex. | 104 | Compound A-13 | Glycine | Colloidal silica | Newcol | 6950 | 220 | 6250 | 500 | 32 |
| 37 | | of the | | (40 nm, 2) | 220L | | | | | |
| | | invention | | | | | | | | |
| Ex. | 105 | Compound A-14 | Glycine | Colloidal silica | Newcol | 7850 | 320 | 6700 | 320 | 15 |
| 38 | | of the | | (40 nm, 2) | 220L | | | | | |
| | | invention | | | | | | | | |
| Ex. | 134 | Compound A-12 | N-Methylglycine | Colloidal silica | PELEX SS-L | 7350 | 420 | 6250 | 320 | 18 |
| 39 | | of the | | (40 nm, 2) | | | | | | |
| | | invention | | | | | | | | |
| Ex. | 135 | Compound A-15 | Oxalic acid | Colloidal silica | NEOPELEX | 5200 | 270 | 4950 | 500 | 32 |
| 40 | | of the | | (40 nm, 2) | No. 6 | | | | | |
| | | invention | | | | | | | | |
| Ex. | 136 | Compound A-18 | N-Methylglycine | Colloidal silica | ELEMINOL | 6800 | 240 | 5000 | 450 | 20 |
| 41 | | of the | | (20 nm, 1) | MON | | | | | |
| | | invention | | | | | | | | |
| Ex. | 137 | Compound A-19 | Tricine | Colloidal silica | ELEMINOL | 6750 | 170 | 5650 | 270 | 18 |
| 42 | | of the | | (20 nm, 2) | MON | | | | | |
| | | invention | | | | | | | | |
| Ex. | 138 | Compound A-26 | Oxalic acid | Colloidal silica | ELEMINOL | 6450 | 305 | 5800 | 530 | 35 |
| 43 | | of the | | (70 nm, 2) | MON | | | | | |
| | | invention | | | | | | | | |
| Ex. | 139 | Compound A-29 | Glycine | Colloidal silica | DOWFAX 2A-1 | 7200 | 310 | 6600 | 320 | 15 |
| 44 | | of the | | (30 nm, 1) | | | | | | |
| | | invention | | | | | | | | |
| Ex. | 140 | Compound A-30 | α-alanine | Colloidal silica | Pionine A- | 7150 | 270 | 6250 | 420 | 27 |
| 45 | | of the | | (30 nm, 1) | 43S | | | | | |
| | | invention | | | | | | | | |
| Ex. | 141 | Compound A-36 | Hydroxy- | Colloidal silica | Newcol | 6350 | 350 | 5770 | 500 | 25 |
| 46 | | of the | ethylglycine | (30 nm, 1) | 220L | | | | | |
| | | invention | | | | | | | | |
| Ex. | 142 | Compound A-37 | Tricine | Colloidal silica | Pionine A- | 7350 | 420 | 7000 | 490 | 18 |
| 47 | | of the | | (30 nm, 1) | 43S | | | | | |
| | | invention | | | | | | | | |
| Ex. | 143 | Compound A-38 | Dihydroxy- | Colloidal silica | — | 6300 | 550 | 4950 | 680 | 55 |
| 48 | | of the | ethylglycine | (30 nm, 1) | | | | | | |
| | | invention | | | | | | | | |
| Ex. | 144 | Compound A-39 | N- | Colloidal silica | NEOPELEX | 7000 | 150 | 5200 | 350 | 20 |
| 49 | | of the | Methylglycine | (30 nm, 1) | No. 6 | | | | | |
| | | invention | | | | | | | | |
| Ex. | 145 | Compound A-40 | α-alanine | Colloidal silica | Pionine A- | 6550 | 140 | 5250 | 270 | 18 |
| 50 | | of the | | (20 nm, 2) | 43-N | | | | | |
| | | invention | | | | | | | | |
| Ex. | 146 | Compound A-41 | Hydroxy- | Colloidal silica | Pionine A- | 6250 | 275 | 5400 | 330 | 32 |
| 51 | | of the | ethylglycine | (30 nm, 2) | 43S | | | | | |
| | | invention | | | | | | | | |
| Ex. | 147 | Compound A-43 | Glycine | Colloidal silica | Pionine A- | 7100 | 280 | 6200 | 420 | 55 |
| 52 | | of the | | (70 nm, 2) | 43S | | | | | |
| | | invention | | | | | | | | |
| Ex. | 148 | Compound A-45 | Tricine | Colloidal silica | — | 6920 | 270 | 5880 | 520 | 62 |
| 53 | | of the | | (40 nm, 1) | | | | | | |
| | | invention | | | | | | | | |
| Ex. 54 | 149 | Compound A-47 | Oxalic acid | Colloidal silica | PELEX SS-L | 6200 | 320 | 5500 | 520 | 25 |
| | | of the | | (40 nm, 2) | | | | | | |
| | | invention | | | | | | | | |
| Ex. 55 | 150 | Compound A-48 | Tricine | Colloidal silica | Pionine A- | 7250 | 420 | 6750 | 490 | 18 |
| | | of the | | (40 nm, 2) | 43S | | | | | |
| | | invention | | | | | | | | |
| Ex. 56 | 151 | Compound A-49 | Dihydroxy- | Colloidal silica | PELEX SS-L | 6100 | 550 | 4520 | 320 | 21 |
| | | of the | ethylglycine | (40 nm, 2) | | | | | | |
| | | invention | | | | | | | | |
| Comp. | 207 | Comparative | Glycine | Colloidal silica | Pionine A- | 5900 | 430 | 4800 | 630 | 142 |
| Ex. 7 | | Compound 1 | | (20 nm, 2) | 43-N | | | | | |
| Comp. | 208 | Comparative | α-alanine | Colloidal silica | Pionine A- | 5550 | 330 | 5200 | 620 | 120 |
| Ex. 8 | | Compound 1 | | (20 nm, 2) | 43-N | | | | | |
| Comp. | 209 | Comparative | Hydroxy- | Colloidal silica | Newcol | 5450 | 500 | 4800 | 650 | 85 |
| Ex. 9 | | Compound 1 | ethylglycine | (40 nm, 2) | 220L | | | | | |
| Comp. | 210 | Comparative | Glycine | Colloidal silica | Pionine A- | 4550 | 450 | 3850 | 730 | 110 |
| Ex. 10 | | Compound 2 | | (40 nm, 2) | 43S | | | | | |
| Comp. | 211 | Comparative | α-alanine | Colloidal silica | Pionine A- | 4350 | 520 | 3950 | 715 | 130 |
| Ex. 11 | | Compound 2 | | (20 nm, 1) | 43S | | | | | |
| Comp. | 212 | Comparative | Dihydroxy- | Colloidal silica | Newcol | 4100 | 460 | 3200 | 680 | 90 |
| Ex. 12 | | Compound 2 | ethylglycine | (40 nm, 2) | 220L | | | | | |

Newcol 220L: sodium dodecylbenzene sulfonate manufactured by Nippon Nyukazai Co., Ltd.
PELEX SS-L: sodium alkyl diphenyl ether disulfonate manufactured by Kao Corporation
NEOPELEX No. 6: dodecylbenzene sulfonate manufactured by Kao Corporation
ELEMINOL MON: sodium dodecylalkyl diphenyl ether disulfonate manufactured by Sanyo Chemical Industries, Ltd.
DOWFAX 2A-1: sodium dodecylalkyl diphenyl ether disulfonate manufactured by DOW
Pionine A-43S: sodium dodecyl diphenyl ether disulfonate manufactured by Takemoto Oil and Fat Co., Ltd.
Pionine A-43-N: ammonium dodecyl alkyl diphenyl ether disulfonate manufactured by Takemoto Oil and Fat Co., Ltd.

As demonstrated in Table 2, compared to single stage polishing method, lower dishing and lower scratch count could be simultaneously realized by employing the first and the second polishing steps.

The advantage of the present invention was particularly significant when the surfactant used was dodecyl diphenyl ether disulfonate, when the organic acid was an amino acid, and when the abrasive had a particle size of 20 to 40 nm.

What is claimed is:

1. A metal polishing slurry used for chemical mechanical polishing in producing a semiconductor device, wherein the metal polishing slurry comprises
a compound represented by the following general formula (1): 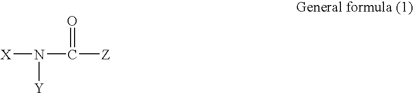
wherein X represents a heterocyclic group containing at least one nitrogen atom, Y represents hydrogen atom, an aliphatic hydrocarbon group, an aryl group, or a —C(═O)Z′ wherein Z′ is as defined for Z, and Z represents hydrogen atom, an optionally substituted aliphatic hydrocarbon group, an optionally substituted aryl group, an optionally substituted heterocyclic group, —NZ¹Z², or —OZ³ wherein Z¹, Z², and Z³ independently represent hydrogen atom, an optionally substituted aliphatic hydrocarbon group, an optionally substituted aryl group, or an optionally substituted heterocyclic group, with the proviso that Y and Z may together form a ring,
an oxidizing agent, and
an organic acid.

2. The metal polishing slurry according to claim 1 wherein Z in the general formula (1) is —NZ¹Z².

3. The metal polishing slurry according to claim 1 or 2 wherein X in the general formula (1) is tetrazole or 1,2,3-triazole.

4. The metal polishing slurry according to claim 1 wherein Y in the general formula (1) is hydrogen atom.

5. The metal polishing slurry according to claim 1 wherein the substituent for the optionally substituted aliphatic hydrocarbon group, aryl group, and heterocyclic group of Z and the optionally substituted aliphatic hydrocarbon group, aryl group, and heterocyclic group of Z¹, Z², and Z³ in the general formula (1) is at least one member selected from hydroxy group, amino group, ether group, amide group, sulfonamide group, sulfonimide group, carboxy group, sulfo group, quaternary ammonium group, imidazolium group, and phospho group.

6. The metal polishing slurry according to claim 1 wherein the aliphatic hydrocarbon group, the aryl group, and the heterocyclic group of Z and the aliphatic hydrocarbon group, the aryl group, and the heterocyclic group of Z¹, Z², and Z³ in the general formula (1) are substituted with hydroxy group.

7. The metal polishing slurry according to claim 1 further comprising an abrasive.

8. The metal polishing slurry according to claim 7 wherein the abrasive is colloidal silica.

9. The metal polishing slurry according to claim 8 wherein the colloidal silica has a primary particle size of 20 to 40 nm and an average degree of association of up to 2.

10. The metal polishing slurry according to claim 8 or 9 wherein the colloidal silica is the colloidal silica in which at least a part of the silicon atoms on the surface are modified with aluminum atom.

11. The metal polishing slurry according to claim 1 further comprising a surfactant represented by the following general formula (2):
R-Ar-O-Ar-SO₃⁻M⁺ General formula (2)
wherein R represents a linear or branched alkyl group containing to 20 carbon atoms, Ar represents aryl group, and M⁺ represents hydrogen ion, an alkali metal ion, or ammonium ion.

12. The metal polishing slurry according to claim 1 wherein the organic acid is amino acid.

13. A chemical mechanical polishing method for polishing an object having a surface to be polished, wherein the metal polishing slurry of claim 1 is supplied to a polishing pad on a polishing platen while rotating the polishing platen to move the polishing pad in relation to the surface to be polished of the object which is in contact with the polishing pad to thereby polish the surface to be polished of the object.
